(19) United States
(12) Patent Application Publication
(10) Pub. No.: US 2022/0208499 A1
(43) Pub. Date: Jun. 30, 2022

(54) POWER CONVERTER AND BREAKING MECHANISM

(71) Applicant: Mitsubishi Electric Corporation, Tokyo (JP)

(72) Inventors: Katsushi NAKADA, Tokyo (JP); Shingo TAKABUCHI, Tokyo (JP); Kenta FUJII, Tokyo (JP)

(73) Assignee: Mitsubishi Electric Corporation, Tokyo (JP)

(21) Appl. No.: 17/503,851

(22) Filed: Oct. 18, 2021

(30) Foreign Application Priority Data
Dec. 24, 2020 (JP) 2020-214467
Dec. 24, 2020 (JP) 2020-214468

(51) Int. Cl. H01H 85/00; H01H 85/046; H01H 85/47; H01H 85/12; H02H 7/12

(52) U.S. Cl. CPC H01H 85/0078; H01H 85/046; H02H 7/1213; H01H 85/12; H01H 85/47

(57) ABSTRACT

To provide a power converter and a breaking mechanism which can break a DC current and can suppress that a fused material scatter to other circuits at fusing, in the case the breaking mechanism of excess current is formed by a circuit pattern of a circuit board. A breaking mechanism is formed by a multilayer circuit board, and is provided with one or two fuse patterns which fuse when excessive current flows, and a scattering prevention pattern, wherein the one or two fuse patterns are provided in an inner layer, and wherein the scattering prevention pattern is provided in a layer different from the one or the two fuse patterns, and overlaps with at least a part of a fusing part of each of the one or two fuse patterns, viewing in a normal direction of a circuit board face.

### INCORPORATION BY REFERENCE

The disclosures of Japanese Patent Application No. 2020-214467 filed on Dec. 24, 2020 and Japanese Patent Application No. 2020-214468 filed on Dec. 24, 2020 including their specifications, claims and drawings, are incorporated herein by reference in its entirety.

### BACKGROUND

The present disclosure relates to a power converter and a breaking mechanism.

In the power converter, when an electronic component, such as a power semiconductor device or a capacitor forming a snubber circuit, is short-circuited in the power supplying state of battery, excessive current flows. If the excess current flows continuously, the power converter is damaged by energization of large current.

Then, previously, when excess current flows, damage of the electrical components is prevented by fusing a current fuse (a tube fuse). The tube fuse is installed in a part through which the short-circuit current of apparatus flows, and the tube fuse fuses by a current larger than the rated current of apparatus.

Unlike the tube fuse, a part of circuit board pattern is formed by a wiring pattern thinner than others, this thin wiring pattern part fuses at the short circuit of an electrical component or a closed circuit, and current is broken (for example, JP 2000-3662 A).

### SUMMARY

However, the technology of JP 2000-3662 A targets the commercial power. Since the commercial power is AC current, the zero point of current exists. Accordingly, even if the arc discharge is generated after fusing of the thin wiring pattern part, when current becomes the zero point, the arc discharge disappears and current is broken. However, in the case of DC current, since the zero point of current does not exist, after fusing of the thin wiring pattern part, the arc discharge is continuously generated and the current continuously flows.

In the technology of JP 2000-3662 A, since the thin wiring pattern part is provided in the outer layer of the circuit board, the fused material scatters to other circuits at fusing, and there is a possibility of damaging the electrical component.

Then, in the case where the breaking mechanism of excess current is formed by a circuit pattern of a circuit board, the purpose of the present disclosure is to provide a power converter and a breaking mechanism which can break DC current and can suppress that a fused material scatter to other circuits at fusing.

A power converter according to the present disclosure including:

a semiconductor element;

a breaking mechanism that breaks current when excessive current flows; and

a wiring member that connects the semiconductor element and the breaking mechanism,

wherein the breaking mechanism is formed by a multilayer circuit board in which a plurality of conductive patterns and a plurality of insulating members are laminated, and is provided with one or two fuse patterns which fuse when excessive current flows, and a scattering prevention pattern,

wherein the one or two fuse patterns are provided in an inner layer, and

wherein the scattering prevention pattern is provided in a layer different from the one or two fuse patterns, and overlaps with at least a part of a fusing part of each of the one or two fuse patterns, viewing in a normal direction of a circuit board face.

A breaking mechanism according to the present disclosure that breaks current when excessive current flows and is formed by a multilayer circuit board in which a plurality of conductive patterns and a plurality of insulating members are laminated, the breaking mechanism including:

one or two fuse patterns which fuse when excessive current flows, and

a scattering prevention pattern,

wherein the one or two fuse patterns are provided in an inner layer, and

wherein the scattering prevention pattern is provided in a layer different from the one or two fuse patterns, and overlaps with at least a part of a fusing part of each of the one or two fuse patterns, viewing in a normal direction of a circuit board face.

According to the power converter and the breaking mechanism of the present disclosure, the arc discharge may be generated after the fuse pattern fuses by excess current. The fuse pattern is disposed in the inner layer and is surrounded by the insulating member of the multilayer circuit board. Therefore, the arc discharge is limited in the space within the insulating member, and the cross-section area of the arc discharge does not become large. Decomposition gas is emitted from the insulating member by exposing the insulating member of the multilayer circuit board to the arc discharge. By the decomposition gas, the cross-section area of the arc discharge becomes smaller than the cross-section area of the space within the insulating member (the ablation effect). As a result, a resistance value of the arc discharge in inverse proportion to the cross-section area of the arc discharge becomes high, and the arc discharge voltage becomes high. Therefore, the arc discharge current which is generated after fusing can be decreased gradually, and the DC current can be broken. Since the fuse pattern is provided in the inner layer, it can be suppressed that the fused material of the fuse pattern and the like scatter to other circuits. The scattering prevention pattern is provided in the layer different from the fuse pattern, and overlaps with at least a fusing part of the fuse pattern, viewing in the normal direction of the circuit board face. Accordingly, the scattering prevention pattern can suppress that the fused material of the fuse pattern and the like scatter to other circuits. The scattering prevention pattern can shield the electromagnetic noise which is generated at the short circuit breaking and in the normal circuit operation, and can suppress giving the adverse influences, such as malfunction, on other electrical components. Moreover, the scattering prevention pattern can radiate and diffuse the heat of fuse pattern generated in the normal circuit operation, and it can suppress the temperature rise of the multilayer circuit board.

### BRIEF DESCRIPTION OF THE DRAWINGS

FIG. 1 is a schematic circuit diagram of the power converter according to Embodiment 1;

FIG. 2 is a plan view of each layer of the breaking mechanism according to Embodiment 1;

FIG. 3 is a cross-sectional view of the breaking mechanism according to Embodiment 1;

FIG. 4 is a circuit diagram explaining the short-circuit current according to Embodiment 1;

FIG. 5 is a figure explaining the characteristics of the arc discharge voltage of the fuse part of the outer layer and the fuse part of the inner layer according to Embodiment 1;

FIG. 6 is a plan view of each layer of the breaking mechanism according to Embodiment 2;

FIG. 7 is a cross-sectional view of the breaking mechanism according to Embodiment 2;

FIG. 8 is a plan view of each layer of the breaking mechanism according to Embodiment 3;

FIG. 9 is a cross-sectional view of the breaking mechanism according to Embodiment 3;

FIG. 10 is a plan view of each layer of the breaking mechanism according to Embodiment 4;

FIG. 11 is a cross-sectional view of the breaking mechanism according to Embodiment 4;

FIG. 12 is a plan view of each layer of the breaking mechanism according to Embodiment 5;

FIG. 13 is a cross-sectional view of the breaking mechanism according to Embodiment 5;

FIG. 14 is a plan view of each layer of the breaking mechanism according to Embodiment 6;

FIG. 15 is a cross-sectional view of the breaking mechanism according to Embodiment 6;

FIG. 16 is a plan view of each layer of the breaking mechanism according to Embodiment 7;

FIG. 17 is a cross-sectional view of the breaking mechanism according to Embodiment 7;

FIG. 18 is a plan view of each layer of the breaking mechanism according to Embodiment 7;

FIG. 19 is a plan view of each layer of the breaking mechanism according to Embodiment 8;

FIG. 20 is a cross-sectional view of the breaking mechanism according to Embodiment 8;

FIG. 21 is a plan view of the breaking mechanism according to other embodiments;

FIG. 22 is a plan view of the breaking mechanism according to other embodiments;

FIG. 23A is a plan view of the shape of the fuse part according to other embodiments;

FIG. 23B is a plan view of the shape of the fuse part according to other embodiments;

FIG. 23C is a plan view of the shape of the fuse part according to other embodiments; and

FIG. 23D is a plan view of the shape of the fuse part according to other embodiments.

### DETAILED DESCRIPTION OF THE EMBODIMENTS

### 1. Embodiment 1

A power converter according to Embodiment 1 will be explained with reference to drawings. The power converter performs a power conversion between a first external connection terminal 1 and a second external connection terminal 2. The power converter is provided with a semiconductor element 3, a breaking mechanism 30 that breaks current when excessive current flows, and a wiring member 25 that connects the semiconductor element 3 and the breaking mechanism 30.

### 1-1. Basic Configuration of Power Converter

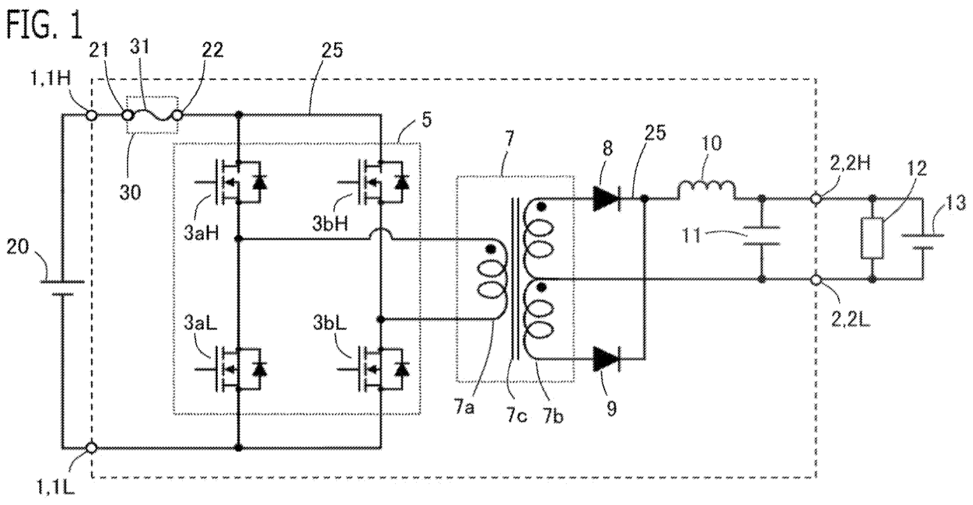

FIG. 1 is a circuit diagram of the power converter. The power converter performs power conversion between the first external connection terminal 1 and the second external connection terminal 2. In the present embodiment, the power converter is an insulated type DC-DC converter. A first side DC power source 20 (in this example, battery) is connected to the first external connection terminal 1. An electric load 12 and a second side DC power source 13 (in this example, battery) are connected to the second external connection terminal 2. A voltage Vin of the first external connection terminal 1 becomes higher than a voltage Vout of the second external connection terminal 2.

Between a high potential side terminal 1H and a low potential side terminal 1L of the first external connection terminal 1, a semiconductor circuit 5 configured by the semiconductor element 3 is connected via the wiring member 25. The semiconductor element 3 is a switching device 3. A diode may be used as the semiconductor element 3. The semiconductor circuit 5 is provided with a first series circuit in which a high potential side switching device 3aH and a low potential side switching device 3aL are connected in series, and a second series circuit in which a high potential side switching device 3bH and a low potential side switching device 3bL are connected in series. A connection node between the high potential side and the low potential side switching devices 3aH, 3aL of the first series circuit is connected to one terminal of a primary winding 7a of a transformer 7 via the wiring member 25. A connection node between the high potential side and the low potential side switching devices 3bH, 3bL of the second series circuit is connected to the other terminal of the primary winding 7a of the transformer 7 via the wiring member 25. The semiconductor circuit 5 is formed in a resin-sealed module shape.

A MOSFET (Metal Oxide Semiconductor Field Effect Transistor) is used as the switching device 3. Other kinds of switching device such as an IGBT (Insulated Gate Bipolar Transistor) in which a diode is connected in reversely parallel may be used as the switching device 3.

A gate terminal of the each switching device is connected to the controller. The controller drives on/off each switching device 3 by PWM control (Pulse Width Modulation), and makes the power converter perform power conversion.

The transformer 7 is provided with the primary winding 7a, a secondary winding 7b, and an iron core 7c in which the primary winding 7a and the secondary winding 7b are wound.

One end of the secondary winding 7b is connected to one end of a reactor 10 via a diode 8 for rectification, and the wiring member 25. The other end of the secondary winding 7b is connected to one end of the reactor 10 via a diode 9 for rectification, and the wiring member 25. The other end of the reactor 10 is connected to a high potential side terminal 2H of the second external connection terminal 2 via the wiring member 25. A center tap (middle point) of the secondary winding 7b is connected to a low potential side terminal 2L of the second external connection terminal 2 via the wiring member 25. A smoothing capacitor 11 is connected between the high potential side terminal 2H and the low potential side terminal 2L of the second external connection terminal 2.

Basic operation of the power converter will be explained briefly. The on/off control of the controller switches repeatedly in order of the first mode, the second mode, the third mode, and the fourth mode.

In the first mode, the high potential side switching device 3aH of the first series circuit and the low potential side switching device 3bL of the second series circuit are turned on, and the low potential side switching device 3aL of the first series circuit and the high potential side switching device 3bH of the second series circuit are turned off. At this time, the current which flows through the primary winding 7a flows in a route of the high potential side terminal 1H->the switching device 3aH->the primary winding 7a->the switching device 3bL->the low potential side terminal 1L. The transformer 7 transmits power from the primary winding 7a to the secondary winding 7b. The current which flows through the secondary winding 7b flows in a route of the low potential side terminal 2L->the secondary winding 7b->the diodes 8, 9->the reactor 10->the high potential side terminal 2H.

In the second mode, all of the four switching devices 3aH, 3aL, 3bH, 3bL are turned off. At this time, current does not flow into the primary winding 7a, and power is not transmitted to the secondary winding 7b. But, on the secondary side, by self-induction of the reactor 10, current flows in a route of the reactor 10->the high potential side terminal 2H->the low potential side terminal 2L->the secondary winding 7b->the diodes 8, 9->the reactor 10. At this time, since voltage is not generated in the secondary side of the transformer 7, the current IL which flows into the reactor 10 decreases.

In the third mode, the high potential side switching device 3aH of the first series circuit and the low potential side switching device 3bL of the second series circuit are turned off, and the low potential side switching device 3aL of the first series circuit and the high potential side switching device 3bH of the second series circuit are turned on. At this time, the current which flows through the primary winding 7a flows in a route of the high potential side terminal 1H->the switching device 3bH->the primary winding 7a->the switching device 3aL->the low potential side terminal 1L. The transformer 7 transmits power from the primary winding 7a to the secondary winding 7b. The current which flows through the secondary winding 7b flows in a route of the low potential side terminal 2L->the secondary winding 7b->the diodes 8, 9->the reactor 10->the high potential side terminal 2H.

In the fourth mode, all of the four switching devices 3aH, 3aL, 3bH, 3bL are turned off. At this time, current does not flow into the primary winding 7a, and power is not transmitted to the secondary winding 7b. But, on the secondary side, by self-induction of the reactor 10, current flows in a route of the reactor 10->the high potential side terminal 2H->the low potential side terminal 2L->the secondary winding 7b->the diodes 8, 9->the reactor 10. At this time, since voltage is not generated in the secondary side of the transformer 7, the current IL which flows into the reactor 10 decreases. In each mode, the AC component of current which flows through the reactor 10 flows into the smoothing capacitor 11, and is smoothed.

The controller changes the on-duty of the switching devices by changing the period of each mode, and controls the output voltage of the second external connection terminal 2.

Herein, when the voltage of the primary winding 7a of the transformer 7 is set to V1, the winding number of the primary winding 7a is set to N1, the current which flows through the primary winding 7a is set to I1, the voltage of the secondary winding 7b is set to V2, the winding number of the secondary winding 7b is set to N2, and the current of the secondary winding 7b is set to I2, the relation of the next equation is established in the first mode and the third mode.

N1/N2=V1/V2=I2/I1 (1)

Herein, N1/N2 is called the turn ratio of the transformer 7. Since the voltage Vin of the first external connection terminal 1 is applied to the primary winding 7a, it is V1=Vin. Accordingly, the next equation is obtained from the equation (1).

V2=Vin/(N1/N2) (2)

As shown in the equation (2), as the voltage V2 of the secondary winding 7b of the transformer 7, a voltage obtained by dividing the voltage Vin of the first external connection terminal 1 applied to the primary winding 7a by the turn ratio N1/N2 is generated. At this time, a difference voltage (=|V2−Vout|) between the voltage V2 of the secondary winding 7b and the voltage Vout of the second external connection terminal 2 is applied to the both ends of the reactor 10. Accordingly, in the first mode and the third mode, the current IL of the reactor 10 increases. At this time, a current obtained by dividing the current IL of the reactor 10 by the turn ratio (=IL/(N1/N2)) flows into the primary winding 7a of the transformer 7.

On the other hand, in the second mode and the fourth mode, since all the switching devices are turned off, the voltage Vin of the first external connection terminal 1 is no longer applied to the primary winding 7a, and it becomes V1=0. Current does not flow into the primary winding 7a, and it becomes I1=0.

At this time, the voltage Vout of the second external connection terminal 2 is applied to the reactor 10. Accordingly, in the second mode and the fourth mode, the current IL of the reactor 10 decreases. Current equivalent to the current IL which flows into the reactor 10 flows into the secondary winding 7b from the center tap, and it becomes I2=IL. Voltage is not generated in the secondary winding 7b of the transformer 7, and it becomes V2=0.

### 1-2. Breaking Mechanism 30

In the present embodiment, the breaking mechanism 30 is connected in series on the wiring member 25 which connects the high potential side terminal 1H of the first external connection terminal 1 and the high potential side of the semiconductor circuit 5. The breaking mechanism 30 breaks current, when the short circuit failure of the switching device 3 occurs, the high potential side terminal 1H and the low potential side terminal 1L of the first external connection terminal 1 are short-circuited, and a short-circuit current flows, for example.

The breaking mechanism 30 is formed by a multilayer circuit board in which a plurality of conductive patterns and a plurality of insulating members are laminated. The breaking mechanism 30 is provided with a fuse pattern 31 which fuses when excessive current flows, and a scattering prevention pattern 40.

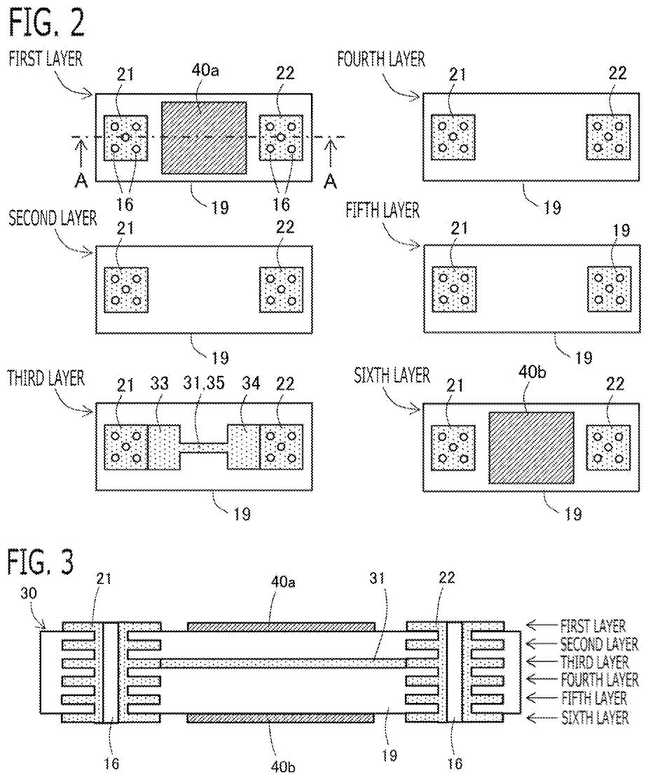

In the present embodiment, the breaking mechanism 30 is formed by the multilayer circuit board of six layers. Herein, the layer means a layer in which a conductive pattern is formed, and includes outer layers which are layers of one outside and the other outside of the multilayer circuit board. FIG. 2 shows a plan view of each layer, and FIG. 3 shows a cross-sectional view which cut the all six layers by a plane perpendicular to the circuit board at the A-A cross section position of FIG. 2.

In the multilayer circuit board, the substrates 19 and the conductive patterns are laminated alternately without gap. The multilayer circuit board is a printed circuit board, for example. That is to say, the conductive pattern of the inner layer is surrounded by the insulation member such as a substrate 19, and is sealed between two sheets of the substrates 19. A slot may be formed in the surface of the substrate 19 and the conductive pattern may be inserted in the slot.

In the present embodiment, five sheets of the substrates 19 are laminated. In both sides layers of the one substrate sheet of the outside or the middle, the conductive patterns are provided; and in the one side layers of the remaining four substrate sheets 19, the conductive patterns are provided. Each substrate 19 is formed in a rectangular plate shape.

The substrate 19 is formed of any materials which have electrical insulation. The substrate 19 is formed of a glass fiber-reinforced epoxy resin, a phenol resin, a polyphenylene sulfide (PPS), a polyether ether ketone (PEEK), or the like, for example. Or, the substrate 19 is formed of a film of polyethylene terephthalate (PET) or polyimide (PI), or a paper formed from aramid (wholly aromatic polyamide) fiber, for example. The substrate 19 may be formed of a ceramic materials, such as an aluminum oxide (Al₂O₃) or aluminum nitride (AlN). The substrate 19 can insulate between the conductive patterns formed in each layer.

As shown in FIG. 2 and FIG. 3, in each layer (surface of each substrate 19), the first terminal pattern 21 and the second terminal pattern 22 are provided with an interval therebetween. Viewing in the normal direction of the circuit board face, the first terminal patterns 21 of respective layers are disposed at a position overlapping with each other. Viewing in the normal direction of the circuit board face, the second terminal patterns 22 of respective layers are disposed at a position overlapping with each other. The first and the second terminal patterns 21, 22 are formed of a copper foil, and are formed in a rectangular plate shape in this example.

The first terminal patterns 21 of respective layers are connected with each other so as to become the same electric potential by a conductive cylindrical tubular through hole 16 which penetrates each substrate 19. In this example, the five through holes 16 are provided. The second terminal patterns 22 of respective layers are connected with each other so as to become the same electric potential by a conductive cylindrical tubular through hole 16 which penetrates each substrate 19. In this example, the five through holes 16 are provided.

The first terminal pattern 21 is connected to the high potential side terminal 1H of the first external connection terminal 1 via the wiring member 25 (for example, a wiring pattern or a harness) which is not shown. The second terminal pattern 22 is connected to the high potential side of the semiconductor circuit 5 via the wiring member 25 (for example, a wiring pattern or a harness) which is not shown. Since the breaking mechanism 30 has no directionality, the first terminal pattern 21 may be connected to the high potential side of the semiconductor circuit 5, and the second terminal pattern 22 may be connected to the high potential side terminal 1H of the first external connection terminal 1.

The fuse pattern 31 is provided in the inner layer. The fuse pattern 31 is connected between the first terminal pattern 21 and the second terminal pattern 22.

In the present embodiment, the fuse pattern 31 is provided in the third layer. The fuse pattern 31 is formed of a copper foil. The fuse pattern 31 is provided with a first terminal side base part 33 connected to the first terminal pattern 21, a second terminal side base part 34 connected to the second terminal pattern 22, and a fuse part 35 which connects between the first terminal side base part 33 and the second terminal side base part 34. The fuse part 35 is sealed within the multilayer circuit board.

A cross-section area of the fuse part 35 becomes smaller than a cross-section area of the first terminal side base part 33 and the second terminal side base part 34. The fuse part 35 is a fusing part which fuses when excess current flows. One or both of the length and the cross-section area of the fuse part 35 are adjusted, and a resistance value [0] of the fuse part 35 is adjusted.

The scattering prevention pattern 40 is provided in a layer different from the fuse pattern 31. Viewing in the normal direction of the circuit board face, the scattering prevention pattern 40 overlaps with at least a part of the fusing part (in this example, the fuse part 35) of the fuse pattern 31.

In the present embodiment, a plurality of scattering prevention patterns 40 (in this example, two) are provided in mutually different layers. The first scattering prevention pattern 40a is provided in a layer on one side rather than the fuse pattern 31. The second scattering prevention pattern 40b is provided in a layer on the other side rather than the fuse pattern 31. The first scattering prevention pattern 40a is provided in the first layer which is an outer layer of one side, and the second scattering prevention pattern 40b is provided in the sixth layer which is an outer layer of the other side.

The first and the second scattering prevention patterns 40a, 40b are formed in a rectangular plate shape which covers the whole fuse part 35. Therefore, the first and the second scattering prevention patterns 40a, 40b overlap with the whole fuse part 35, viewing in the normal direction of the circuit board face. The first and the second scattering prevention patterns 40a, 40b are formed of a copper foil. The first and the second scattering prevention patterns 40a, 40b are not electrically connected to the fuse pattern 31, and these are different potentials.

### <Fusing by Short-Circuit Current>

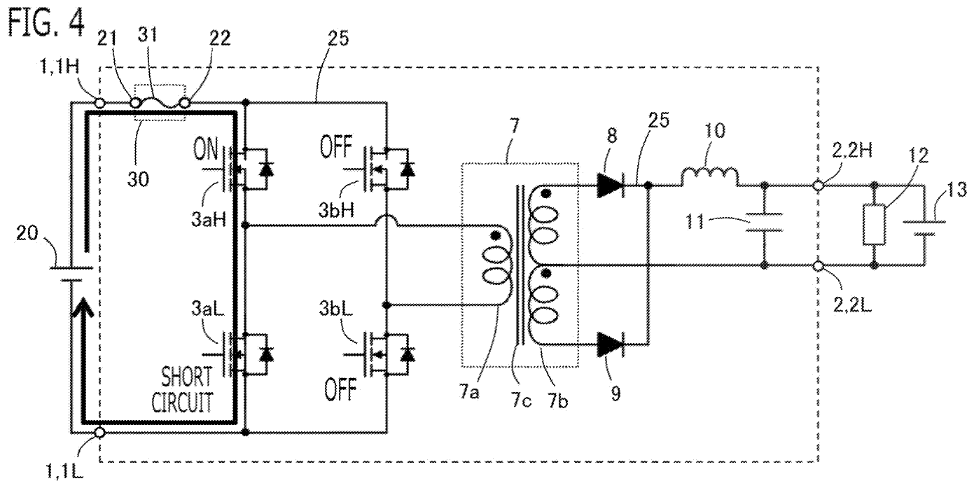

Herein, using an example that the switching device is short-circuited in the first mode, a behavior of the fuse pattern and a breaking principle of the DC current will be explained. As shown in FIG. 4, when the low potential side switching device 3aL of the first series circuit which is turned off is short-circuited in the first mode, the first series circuit is short-circuited, and a short-circuit current flows through the breaking mechanism 30.

The short-circuit current is larger than the current in normal operation. And, since the cross-section area of the fuse part 35 is smaller than other parts, and the resistance value of the fuse part 35 is larger than other parts, the heating amount of the fuse part 35 becomes large, and the fuse part 35 fuses.

When the fuse part 35 fuses, the arc discharge is generated so as to connect the both ends of the fuse part 35. Since the zero point of current does not exist if the current to break is a DC current, the arc discharge is continuously generated even if the wiring pattern is fused, it electrically connects, and current continuously flows. When current continuously flows, the switching devices 3aH, 3aL, or other electronic components and wiring patterns within the closed circuit generate heat, and the power converter may be damaged. Accordingly, it is necessary to forcibly limit current, create a zero point, and break the arc discharge.

A circuit equation of the closed circuit of FIG. 4 becomes the equation (3).

Vin=i×(R+r)+L×di/dt (3)

Herein, Vin is a voltage of the first external connection terminal 1, i is a current which flows through the closed circuit, R is a resistance value of the closed circuit except the fuse part, r is a resistance value of the fuse part (it is a resistance value of the arc discharge after generation of the arc discharge), L is a reactance of the closed circuit, and t is time.

Since after generation of the arc discharge of the fuse part which can limit current, it becomes R<<r, and it can be approximated to (R+r)≈r, the equation (3) can be modified into the equation (4).

di/dt=(Vin−i×r)/L (4)

According to the equation (4), since it is necessary to make di/dt of the left side a negative value (di/dt<0) in order to limit current, it is necessary to make the arc discharge voltage (i×r) higher than the voltage Vin of the first external connection terminal 1. In order to make the arc discharge voltage higher, the resistance value r of the arc discharge needs to be increased. The resistance value r of the arc discharge is generally expressed by the equation (5).

r=L/(σ×Ar) (5)

Herein, L is a length [m] of the arc discharge, σ is an electric conductivity [S/m] of the arc discharge, and Ar is a cross-section area [m²] of the arc discharge.

According to the equation (5), in order to increase the resistance value r of the arc discharge, the length L of the arc discharge may be longer, or the diameter of the arc discharge may be smaller to decrease the cross-section area Ar, or the electric conductivity a of the arc discharge may be smaller.

### Comparative Example

As a comparative example, a case where the fuse pattern is provided in the outer layer of the circuit board is considered. In the comparative example, the arc discharge which is generated in the outer layer can change freely in the air, and the diameter of the arc discharge is not limited. Therefore, the diameter of arc discharge becomes large, and the cross-section area Ar of the arc discharge becomes large. Accordingly, the resistance value r of the arc discharge and the arc discharge voltage (i×r) become small, di/dt of the equation (4) may become a positive value, and current may not be broken.

In the comparative example, the fused material and the conductive material of the fuse pattern in the outer layer scatter to other circuits, and there is a possibility of damaging the electrical component. And, in the comparative example, since it is difficult to provide the scattering prevention pattern which covers the fuse pattern in the outer layer, the electromagnetic noise in the normal circuit operation and at the short circuit breaking cannot be shielded, the electromagnetic noise may give an adverse influence on other electrical components, and may cause malfunction.

Moreover, in the comparative example, since the part of the fuse pattern in the outer layer whose the cross-section area becomes small has a resistance value larger than other parts, the heating amount in the normal circuit operation becomes large, and the thermal diffusion is low since it is provided in the outer layer. Accordingly, the temperature of the fuse pattern becomes high, and in the worst case, there is a possibility of damaging.

### <Effect of Fuse Part and Scattering Prevention Pattern>

Then, in the present embodiment, as mentioned above, the fuse pattern 31 is provided in the inner layer of the multilayer circuit board.

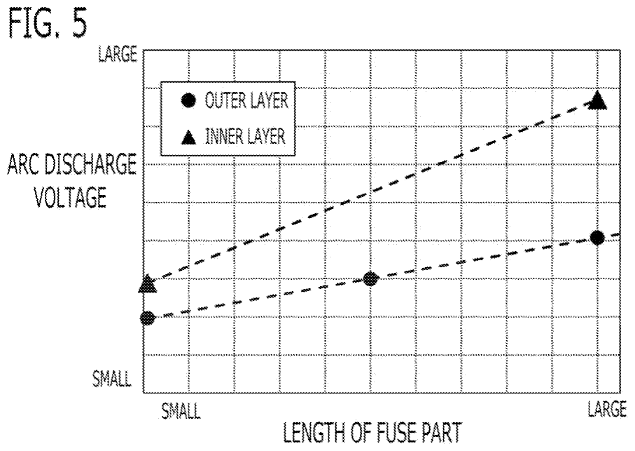

FIG. 5 shows the measured result of the arc discharge voltage when the fuse pattern (the fuse part) is disposed in the inner layer and when the fuse pattern is disposed in the outer layer. As the length of the fuse part whose the cross-section area is small becomes longer, the arc discharge voltage becomes higher. The arc discharge voltage of the fuse part disposed in the inner layer becomes higher than the arc discharge voltage of the fuse part disposed in the outer layer.

The fuse part 35 is disposed in the inner layer, and is surrounded by the substrate 19. Accordingly, the arc discharge is limited in the space within the substrate 19, and the cross-section area Ar of the arc discharge does not become large. Decomposition gas is emitted from the substrate 19 by exposing the substrate 19 to the arc discharge. By the decomposition gas, the cross-section area Ar of the arc discharge becomes smaller than the cross-section area of the space within the substrate 19 (the ablation effect). As a result, as shown in the equation (5), the resistance value r of the arc discharge in inverse proportion to the cross-section area Ar of the arc discharge becomes high, and the arc discharge voltage (i×r) becomes high. Therefore, di/dt of the equation (4) can be made a negative value, the arc discharge current which is generated after fusing can be decreased gradually, and current can be broken.

As shown in the equation (5), as the length L of the arc discharge becomes longer, the resistance value r of the arc discharge becomes larger. As shown in the equation (4), the length of the fuse part 35 is set so that the arc discharge voltage (i×r) becomes larger than the predetermined voltage Vin of the first external connection terminal 1 and di/dt becomes a negative value. As long as the fuse part 35 fuses, the shape of the fuse part 35, such as the cross-section area and the length, can be set to any shape.

And, in the present embodiment, as mentioned above, the scattering prevention pattern 40 is provided in the layer different from the fuse pattern 31, and overlaps with at least a part of the fuse pattern 31, viewing in the normal direction of the circuit board face.

According to this configuration, the scattering prevention pattern 40 can suppress that the fused material and the conductive material of the fuse pattern 31 scatter to other circuits. Since the scattering prevention pattern 40 is made of metal, it can shield the electromagnetic noise at the short circuit breaking, and can suppress giving the adverse influence, such as malfunction, on other electrical components. Although the electromagnetic noise is generated when current flows through the fuse part 35 having the small cross-section area in the normal circuit operation, the scattering prevention pattern 40 can shield the electromagnetic noise. Moreover, the scattering prevention pattern 40 can radiate and diffuse the heat of the fuse pattern generated in the normal circuit operation, and it can suppress the temperature rise of the multilayer circuit board. In the present embodiment, since the scattering prevention pattern 40 is provided in the outer layer, the heat dissipation from the scattering prevention pattern 40 to the outside can be increased, and the heat radiation effect by the scattering prevention pattern 40 is increased.

In the present embodiment, the first scattering prevention pattern 40a is provided in the layer on one side rather than the fuse pattern 31, and the second scattering prevention pattern 40b is provided in the layer on the other side rather than the fuse pattern 31. Therefore, it can prevent the fused material and the conductive material of the fuse pattern 31 from scattering to the one side and the other side of the breaking mechanism 30. Since the first and the second scattering prevention patterns 40a, 40b are disposed so as to cover the whole fuse part 35, the scattering preventing effect, the shielding effect of the electromagnetic noise, and the heat radiation effect are increased.

The voltage applied to the first terminal pattern 21 and the second terminal pattern 22 of the breaking mechanism 30 (in this example, the voltage Vin of the first external connection terminal 1) is not specified. But, generally, when the applied voltage exceeds 20V, the arc discharge is easily generated, and it becomes easy to obtain the breaking effect of the arc discharge of the present disclosure. That is to say, if the voltage supplied to the breaking mechanism 30 is a DC voltage greater than or equal to 20V, it is easy to obtain the breaking effect of the arc discharge of the present disclosure. Even if the supply voltage is less than 20V and the arc discharge is not generated after fusing, the scattering preventing effect of the fused material is obtained by providing the fuse pattern in the inner layer, and the scattering preventing effect of the fused material, the shielding effect of the electromagnetic noise, and the heat radiation effect are obtained by providing the scattering prevention pattern 40.

### 2. Embodiment 2

Next, the power converter according to Embodiment 2 will be explained. The explanation for constituent parts the same as those in Embodiment 1 will be omitted. The basic configuration of the power converter according to the present embodiment is the same as that of Embodiment 1. The configuration of the first and the second scattering prevention patterns 40a, 40b is different from that of Embodiment 1.

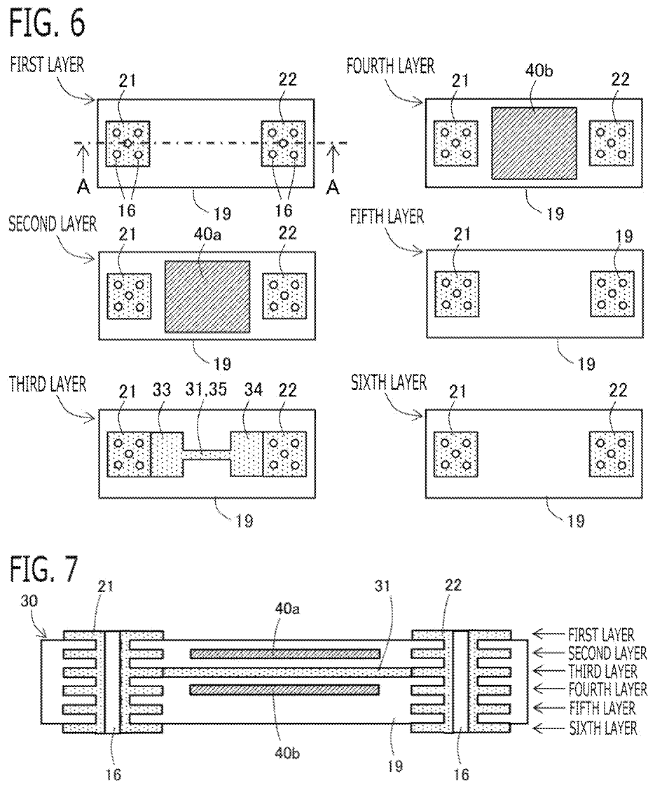

Similar to Embodiment 1, the breaking mechanism 30 is formed by the multilayer circuit board of six layers. FIG. 6 shows a plan view of each layer, and FIG. 7 shows a cross-sectional view which cut the all six layers by a plane perpendicular to the circuit board at the A-A cross section position of FIG. 6.

Since the first terminal pattern 21 and the second terminal pattern 22 are configured similar to Embodiment 1, detailed explanation is omitted. Since the fuse pattern 31 is configured similar to Embodiment 1, detailed explanation is omitted.

Even in the present embodiment, the scattering prevention pattern 40 is provided in the layer different from the fuse pattern 31, and overlaps with at least a part of the fusing part (in this example, the fuse part 35) of the fuse pattern 31, viewing in the normal direction of the circuit board face.

Even in the present embodiment, a plurality of scattering prevention patterns 40 are provided in mutually different layers. The first scattering prevention pattern 40a is provided in the layer on one side rather than the fuse pattern 31, and the second scattering prevention pattern 40b is provided in the layer on the other side rather than the fuse pattern 31.

Unlike Embodiment 1, the first scattering prevention pattern 40a and the second scattering prevention pattern 40b are provided in the inner layer. The first scattering prevention pattern 40a is provided in the second layer of the inner layer, and the second scattering prevention pattern 40b is provided in the fourth layer of the inner layer. The first and the second scattering prevention patterns 40a, 40b are provided in the adjacent layers of the fuse pattern 31, respectively. The second scattering prevention pattern 40b may be provided in the fifth layer of the inner layer.

By providing the scattering prevention pattern 40 in the inner layer, the scattering prevention pattern 40 can be disposed close to the fuse part 35, and the scattering preventing effect, the shielding effect of the electromagnetic noise, and the heat radiation effect by the scattering prevention pattern 40 can be increased.

By providing the scattering prevention pattern 40 in the inner layer, since the both sides of the scattering prevention pattern 40 are reinforced by the substrate 19, the strength of the scattering prevention pattern 40 can be increased rather than the case of providing in the outer layer. Accordingly, the scattering preventing effect by the scattering prevention pattern 40 can be increased.

### 3. Embodiment 3

Next, the power converter according to Embodiment 3 will be explained. The explanation for constituent parts the same as those in each of Embodiments 1 and 2 will be omitted. The basic configuration of the power converter according to the present embodiment is the same as that of Embodiment 1 or 2. But, the configuration of the scattering prevention pattern 40 is different from that of Embodiment 1 or 2.

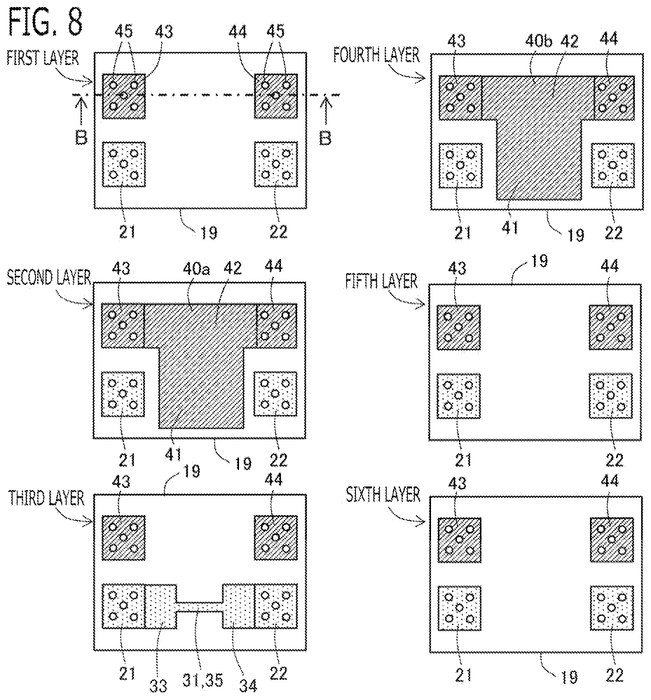

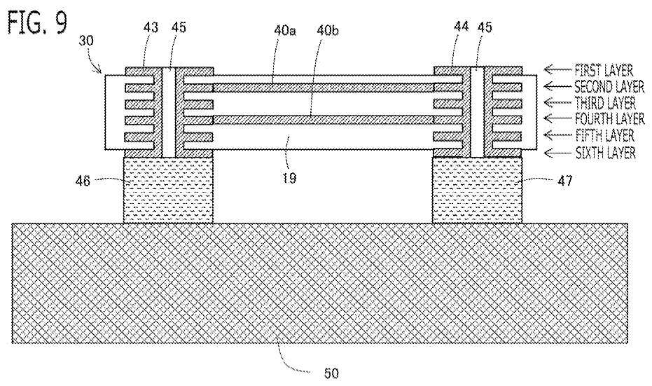

Similar to Embodiment 1, the breaking mechanism 30 is formed by the multilayer circuit board of six layers. FIG. 8 shows a plan view of each layer, and FIG. 9 shows a cross-sectional view which cut the all six layers by a plane perpendicular to the circuit board at the B-B cross section position of FIG. 8.

In the present embodiment, the width of the multilayer circuit board becomes longer than other embodiments. The width is a distance of the circuit board in the direction orthogonal to the extending direction of the fuse part. Since the first terminal pattern 21 and the second terminal pattern 22 are configured similar to Embodiment 1, in a part of the circuit board on one side in the width direction, detailed explanation is omitted. Since the fuse pattern 31 is configured similar to Embodiment 1, in the part of the circuit board on one side in the width direction, detailed explanation is omitted.

Similar to Embodiment 2, the first scattering prevention pattern 40a is provided in the layer on one side rather than the fuse pattern 31 (in this example, the second layer), and the second scattering prevention pattern 40b is provided in the layer on the other side rather than the fuse pattern 31 (in this example, the fourth layer).

In the present embodiment, the scattering prevention pattern 40 is thermally connected to a heat dissipation member 50. Each scattering prevention pattern 40 is provided with a main part 41 which overlaps with the fuse part 35, viewing in the normal direction of the circuit board face, and a connection part 42 which connects the main part 41 with the heat dissipation member 50 side. The connection part 42 extends from the main part 41 to the other side in the width direction. The connection part 42 is formed of the copper foil similar to the main part 41.

In each layer, the first connection pattern 43 is provided on the other side in the width direction of the first terminal pattern 21 with an interval. The second connection pattern 44 is provided on the other side in the width direction of the second terminal pattern 22 with an interval. The first connection patterns 43 of respective layers are disposed at a position overlapping with each other, viewing in the normal direction of the circuit board face. The first connection patterns 43 of respective layers are connected with each other so as to become the same electric potential by a conductive cylindrical tubular through hole 45 (in this example, five through holes) which penetrates each substrate 19. The second connection patterns 44 of respective layers are disposed at a position overlapping with each other, viewing in the normal direction of the circuit board face. The second connection patterns 44 of respective layers are connected with each other so as to become the same electric potential by a conductive cylindrical tubular through hole 45 (in this example, five through holes) which penetrates each substrate 19. The first and the second connection patterns 43, 44 are formed of a copper foil, and are formed in a rectangular plate shape in this example.

The connection part 42 of each scattering prevention pattern 40 is thermally and electrically connected to the first and the second connection patterns 43, 44 of each layer. The first connection pattern 43 in the outer layer (in this example, the sixth layer) is thermally and electrically connected to the heat dissipation member 50 via a first connection member 46. The second connection pattern 44 in the outer layer (in this example, the sixth layer) is thermally and electrically connected to the heat dissipation member 50 via a second connection member 47. Accordingly, each scattering prevention pattern 40 is thermally and electrically connected to the heat dissipation member 50 via the first and the second connection patterns 43, 44, and the first and the second connection members 46, 47. The scattering prevention pattern 40 of each layer is thermally and electrically firmly connected to the heat dissipation member 50 by the first and the second connection patterns 43, 44 of each layer and the through holes 45.

The heat dissipation member 50 is a heatsink, a cooler in which a refrigerant circulates, or the like. The heat dissipation member 50 is disposed with an interval from the breaking mechanism 30.

According to this configuration, the temperature of the scattering prevention pattern 40 becomes low by the heat dissipation member 50, the effect of radiating and diffusing heat of the fuse part to the scattering prevention pattern 40 is improved, and the temperature rise of the circuit board can be suppressed.

In the present embodiment, the scattering prevention pattern 40 has aground potential. The heat dissipation member 50 is connected to the ground. Each scattering prevention pattern 40 is connected to the ground via the first and the second connection patterns 43, 44, the first and the second connection members 46, 47, and the heat dissipation member 50. According to this configuration, the shielding effect of the electromagnetic noise by the scattering prevention pattern 40 can be increased. The scattering prevention pattern 40 and the fuse pattern are different potentials. The heat dissipation member 50 may be floating potential, and the scattering prevention pattern 40 may be floating potential. The scattering prevention pattern 40 may be only thermally connected with the heat dissipation member 50, and may not be electrically connected with the heat dissipation member 50.

The thermal conductivity of the heat dissipation member 50 is preferably greater than or equal to 0.1 W/(m·K). The thermal conductivity of the heat dissipation member 50 is more preferably greater than or equal to 1.0 W/(m·K). The thermal conductivity of the heat dissipation member 50 is further preferably greater than or equal to 10.0 W/(m·K).

The heat dissipation member 50 is preferably formed of a rigid material. Specifically, the heat dissipation member 50 is formed of any metallic material selected from a group which consists of copper (Cu), aluminum (Al), iron (Fe), iron alloy such as SUS304, copper alloy such as phosphor bronze, and aluminum alloy such as ADC12. Alternatively, the heat dissipation member 50 may be formed of a resin material containing a thermally conductive filler. Herein, as the resin material, for example, poly butylene terephthalate (PBT), polyphenylene sulfide (PPS), polyether ether ketone (PEEK), or the like is used. A surface of the heat dissipation member 50 which is different from the surface connected to the connection members 46, 47 may be cooled by a refrigerant of air or fluid.

If the connecting members 46, 47 are integrally constituted with the heat dissipation member 50, the connecting members 46, 47 become the same material as the above heat dissipation member 50. If the connecting members 46, 47 are constituted separately from the heat dissipation member 50, the connecting members 46, 47 may be the same material as the heat dissipation member 50, or may be a material different from the heat dissipation member 50. The heat dissipation member 50 is formed by cutting, die-casting, forging, metal molding, or the like, for example.

The scattering prevention pattern 40 may be thermally and electrically connected to the heat dissipation member 50 without interposing the connecting members 46, 47. For example, the first and the second connection patterns 43, 44 in the outer layer, or the scattering prevention pattern 40 in the outer layer may be thermally and electrically directly connected to the heat dissipation member 50. The layer arrangement of the scattering prevention patterns 40 may be made similar to that of Embodiment 1.

### 4. Embodiment 4

Next, the power converter according to Embodiment 4 will be explained. The explanation for constituent parts the same as those in Embodiment 1 will be omitted. The basic configuration of the power converter according to the present embodiment is the same as that of Embodiment 1. But, the configuration of the fuse pattern is different from that of Embodiment 1.

Similar to Embodiment 1, the breaking mechanism 30 is formed by a multilayer circuit board in which a plurality of conductive patterns and a plurality of insulating members are laminated. In the present embodiment, the breaking mechanism 30 is provided with the first terminal pattern 21 and the second terminal pattern 22 which are connected to the wiring member 25, a first fuse pattern 31a and a second fuse pattern 31b which are connected in parallel between the first terminal pattern 21 and the second terminal pattern 22, and the scattering prevention pattern 40.

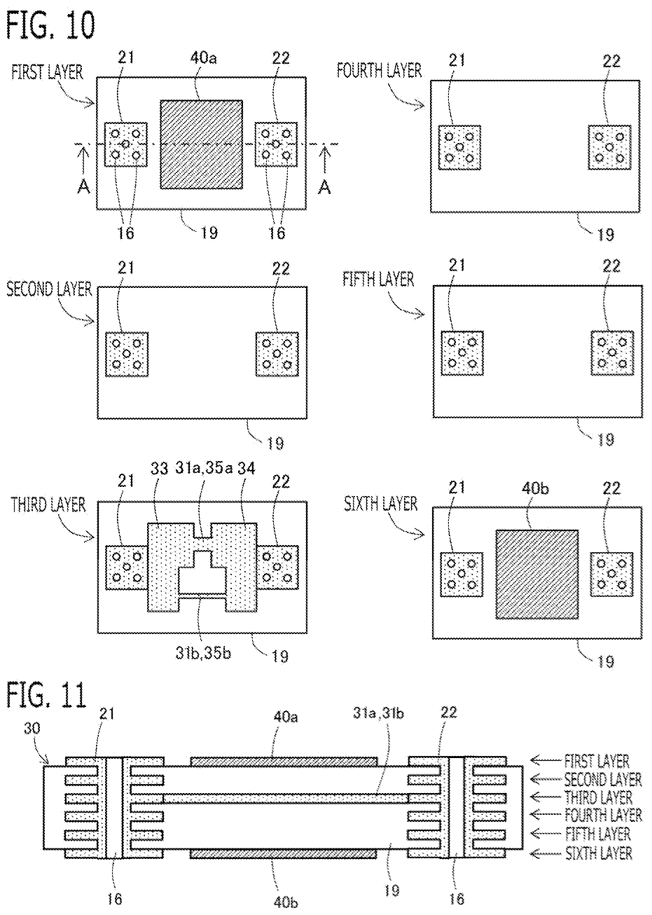

In the present embodiment, the breaking mechanism 30 is formed by the multilayer circuit board of six layers. Herein, the layer means a layer in which a conductive pattern is formed, and includes outer layers which are layers of one outside and the other outside of the multilayer circuit board. FIG. 10 shows a plan view of each layer, and FIG. 11 shows a cross-sectional view which cut the all six layers by a plane perpendicular to the circuit board at the A-A cross section position of FIG. 10.

In the multilayer circuit board, the substrates 19 and the conductive patterns are laminated alternately without gap. The multilayer circuit board is a printed circuit board, for example. That is to say, the conductive pattern of the inner layer is surrounded by the insulation member such as a substrate 19, and is sealed between two sheets of the substrates 19. A slot may be formed in the surface of the substrate 19 and the conductive pattern may be inserted in the slot.

In the present embodiment, five sheets of the substrates 19 are laminated. In both sides layers of the one substrate sheet of the outside or the middle, the conductive patterns are provided; and in the one side layers of the remaining four substrate sheets 19, the conductive patterns are provided. Each substrate 19 is formed in a rectangular plate shape.

The first fuse pattern 31 and the second fuse pattern 31 are provided in inner layers. The first fuse pattern 31a and the second fuse pattern 31b are connected in parallel between the first terminal pattern 21 and the second terminal pattern 22.

In the present embodiment, the first fuse pattern 31a and the second fuse pattern 31b are provided in the same layer (in this example, the third layer). The first fuse pattern 31a and the second fuse pattern 31b are formed of a copper foil. The first fuse pattern 31a and the second fuse pattern 31b are one common pattern, and are provided with a first terminal side base part 33 connected to the first terminal pattern 21, a second terminal side base part 34 connected to the second terminal pattern 22, and a first fuse part 35a and a second fuse part 35b which are connected in parallel between the first terminal side base part 33 and the second terminal side base parts 34. The first fuse part 35a and the second fuse part 35b are sealed within the multilayer circuit board.

A cross-section areas of the first fuse part 35a and the second fuse part 35b become smaller than the cross-section areas of the first terminal side base part 33 and the second terminal side base part 34. The first fuse part 35a and the second fuse part 35b are fusing parts which fuse when excess current flows. A resistance value of the first fuse part 35a is different from a resistance value of the second fuse part 35b. One or both of the length and the cross-section area of each of the first fuse part 35a and the second fuse part 35b are adjusted, and a resistance value [Ω] of each fuse part is adjusted. The resistance value Ra [Ω] of the first fuse part 35a becomes smaller than the resistance value Rb [Ω] of the second fuse part 35b (Ra<Rb). The length of the first fuse part 35a is shorter than the length of the second fuse part 35b, and the cross-section area of the first fuse part 35a becomes larger than the cross-section area of the second fuse part 35b.

The scattering prevention pattern 40 is provided in a layer different from the first fuse pattern 31a and the second fuse pattern 31b. Viewing in the normal direction of the circuit board face, the scattering prevention pattern 40 overlaps with at least a part of the fusing part (in this example, the first fuse part 35a) of the first fuse pattern 31a, and at least a part of the fusing part (in this example, the second fuse part 35b) of the second fuse pattern 31b.

In the present embodiment, a plurality of scattering prevention patterns 40 (in this example, two) are provided in mutually different layers. The first scattering prevention pattern 40a is provided in the layer on one side rather than the first fuse pattern 31a and the second fuse pattern 31b, and the second scattering prevention pattern 40b is provided in the layer on the other side rather than the first fuse pattern 31a and the second fuse pattern 31b. The first scattering prevention pattern 40a is provided in the first layer which is the outer layer of one side, and the second scattering prevention pattern 40b is provided in the sixth layer which is the outer layer of the other side.

The first and the second scattering prevention patterns 40a, 40b are formed in a rectangular plate shape which covers whole of the first fuse part 35a and the second fuse part 35b. Therefore, the first and the second scattering prevention patterns 40a, 40b overlap with whole of the first fuse part 35a and the second fuse part 35b, viewing in the normal direction of the circuit board face. The first and the second scattering prevention patterns 40a, 40b are formed of a copper foil. The first and the second scattering prevention patterns 40a, 40b are not electrically connected to the first fuse pattern 31a and the second fuse pattern 31b, and these are different potentials.

### <Fusing by Short-Circuit Current>

Herein, using an example that the switching device is short-circuited in the first mode, a behavior of the each fuse pattern and a breaking principle of the DC current will be explained. As shown in FIG. 4, when the low potential side switching device 3aL of the first series circuit which is turned off is short-circuited in the first mode, the first series circuit is short-circuited, and a short-circuit current flows through the breaking mechanism 30.

The short-circuit current is larger than the current in normal operation. And, since the cross-section areas of the first and the second fuse part 35a, 35b are smaller than other parts, and the resistance values of the first and the second fuse part 35a, 35b are larger than other parts, the heating amounts of the first and the second fuse part 35a, 35b become large, and the first and the second fuse part 35a, 35b fuse. Since the first fuse part 35a and the second fuse part 35b are electrically connected in parallel, the short-circuit current is divided.

Herein, when the short-circuit current [A] is set to Ishort, a current [A] which flows into the first fuse part 35a is set to Ia, a current [A] which flows into the second fuse part 35b is set to Ib, the next equation is established.

Ishort−Ia+Ib (6)

As shown in the next equation, a ratio of Ia and Ib becomes equal to a ratio of the resistance value Ra [Ω] of the first fuse part 35a and the resistance value Rb [Ω] of the second fuse part 35b.

Ia:Ib=Ra:Rb (7)

A heating amount Wa [W] of the first fuse part 35a and a heating amount Wb [W] of the second fuse part 35b when the short-circuit current flows are calculated by the equation (8) and the equation (9).

Wa=Ia²×Ra (8)

Wb=Ib²×Rb (9)

According to the equation (7) to the equation (9), the ratio of the heating amounts becomes the next equation.

Wa:Wb=Rb:Ra (10)

If the shape of the first fuse part 35a and the second fuse part 35b is determined so that it becomes Ra<Rb, it becomes Wa>Wb. Accordingly, when the short-circuit current flows to the breaking mechanism 30, the first fuse part 35a with large heating amount fuses first. After the first fuse part 35a fused, since all the short-circuit current concentrates on the second fuse part 35b, the second fuse part 35b fuses.

When the second fuse part 35b fused, the arc discharge is generated so as to connect the both ends of the second fuse part 35b. Since the zero point of current does not exist if the current to break is a DC current, the arc discharge is continuously generated even if the wiring pattern is fused, it electrically connects, and current continuously flows. When current continuously flows, the switching devices 3aH, 3aL, or other electronic components and wiring patterns within the closed circuit generate heat, and the power converter may be damaged. Accordingly, it is necessary to forcibly limit current, create a zero point, and break the arc discharge.

A circuit equation of the closed circuit of FIG. 4 becomes the equation (11).

Vin=i×(R+r)+L×di/dt (11)

Herein, Vin is a voltage of the first external connection terminal 1, i is a current which flows through the closed circuit, R is a resistance value of the closed circuit except the fuse part, r is a resistance value of the fuse part (it is a resistance value of the arc discharge after generation of the arc discharge), L is a reactance of the closed circuit, and t is time.

Since after generation of the arc discharge of the fuse part which can limit current, it becomes R<<r, and it can be approximated to (R+r)≈r, the equation (11) can be modified into the equation (12).

di/dt=(Vin−i×r)/L (12)

According to the equation (12), since it is necessary to make di/dt of the left side a negative value (di/dt<0) in order to limit current, it is necessary to make the arc discharge voltage (i×r) higher than the voltage Vin of the first external connection terminal 1. In order to make the arc discharge voltage higher, the resistance value r of the arc discharge needs to be increased. The resistance value r of the arc discharge is generally expressed by the equation (13).

r=L/(σ×Ar) (13)

Herein, L is a length [m] of the arc discharge, a is an electric conductivity [S/m] of the arc discharge, and Ar is a cross-section area [m²] of the arc discharge.

According to the equation (13), in order to increase the resistance value r of the arc discharge, the length L of the arc discharge may be longer, or the diameter of the arc discharge may be smaller to decrease the cross-section area Ar, or the electric conductivity a of the arc discharge may be smaller.

### Comparative Example

As a comparative example, a case where the fuse pattern is provided in the outer layer of the circuit board is considered. In the comparative example, the arc discharge which is generated in the outer layer can change freely in the air, and the diameter of the arc discharge is not limited. Therefore, the diameter of arc discharge becomes large, and the cross-section area Ar of the arc discharge becomes large. Accordingly, the resistance value r of the arc discharge and the arc discharge voltage (i×r) become small, and di/dt of the equation (12) may become a positive value, and current may not be broken.

In the comparative example, the fused material and the conductive material of the fuse pattern in the outer layer scatter to other circuits, and there is a possibility of damaging the electrical component. And, in the comparative example, since it is difficult to provide the scattering prevention pattern which covers the fuse pattern in the outer layer, the electromagnetic noise in the normal circuit operation and at the short circuit breaking cannot be shielded, the electromagnetic noise may give an adverse influence on other electrical components, and may cause malfunction.

Moreover, in the comparative example, since the part of the fuse pattern in the outer layer whose the cross-section area becomes small has a resistance value larger than other parts, the heating amount in the normal circuit operation becomes large, and the thermal diffusion is low since it is provided in the outer layer. Accordingly, the temperature of the fuse pattern becomes high and, in the worst case, there is a possibility of damaging.

### <Effect of Fuse Part and Scattering Prevention Pattern>

In the present embodiment, as mentioned above, the first fuse pattern 31 and the second fuse pattern 31 are provided in the inner layers of the multilayer circuit board, and the resistance values are different with each other.

As explained in Embodiment 1, FIG. 5 shows measured result of the arc discharge voltage when the fuse pattern (the fuse part) is disposed in the inner layer and when the fuse pattern is disposed in the outer layer. As the length of the fuse part whose the cross-section area is small becomes longer, the arc discharge voltage becomes higher. The arc discharge voltage of the fuse part disposed in the inner layer becomes higher than the arc discharge voltage of the fuse part disposed in the outer layer.

In the present embodiment, as explained using the equation (10), after the first fuse part 35a with the small resistance value fuses first, the second fuse part 35b fuses. Accordingly, the arc discharge is generated in the second fuse part 35b. The second fuse part 35b is disposed in the inner layer, and is surrounded by the substrate 19. Therefore, the arc discharge is limited in the space within the substrate 19, and the cross-section area Ar of the arc discharge does not become large. The cross-section area of the second fuse part 35b with the larger resistance value becomes smaller than the cross-section area of the first fuse part 35a with the smaller resistance value. Decomposition gas is emitted from the substrate 19 by exposing the substrate 19 to the arc discharge. By the decomposition gas, the cross-section area Ar of the arc discharge becomes smaller than the cross-section area of the space within the substrate 19 (the ablation effect). As a result, as shown in the equation (13), the resistance value r of the arc discharge in inverse proportion to the cross-section area Ar of the arc discharge becomes high, and the arc discharge voltage (i×r) becomes high. Therefore, di/dt of the equation (12) can be made a negative value, the arc discharge current which is generated after fusing can be decreased gradually, and current can be broken.

As shown in the equation (13), as the length L of the arc discharge becomes longer, the resistance value r of the arc discharge becomes larger. As shown in the equation (12), the length of the second fuse part 35b is set so that the arc discharge voltage (i×r) becomes larger than the predetermined voltage Vin of the first external connection terminal 1 and di/dt becomes a negative value.

As long as the resistance value Ra [Ω] of the first fuse part 35a becomes smaller than the resistance value Rb [Ω] of the second fuse part 35b (Ra<Rb), and the first fuse part 35a fuses earlier than the second fuse part 35b, the shape of the first fuse part 35a, such as the cross-section area and the length, can be set to any shape.

In the normal circuit operation in which the short-circuit current does not flow, since current flows through the first fuse part 35a more than the second fuse part 35b, the heat generation of the second fuse part 35b can be suppressed more than the case of providing only the second fuse part 35b which can limit the arc discharge. Accordingly, by providing the first fuse part 35a and the second fuse part 35b which are connected in parallel, the first fuse part 35a can be designed considering the heat generation in the normal circuit operation, and the second fuse part 35b can be designed considering the limitation of the arc discharge when the short-circuit current flows.

And, in the present embodiment, as mentioned above, the scattering prevention pattern 40 is provided in a layer different from the first fuse pattern 31a and the second fuse pattern 31b. And, viewing in the normal direction of the circuit board face, the scattering prevention pattern 40 overlaps with at least a part of the first fuse pattern 31a, and at least a part of the second fuse pattern 31b.

According to this configuration, the scattering prevention pattern 40 can suppress that the fused material and the conductive material of the first fuse part 35a and the second fuse part 35b scatter to other circuits. Since the scattering prevention pattern 40 is made of metal, it can shield the electromagnetic noise at the short circuit breaking, and can suppress giving the adverse influence, such as malfunction, on other electrical components. Although the electromagnetic noise is generated when current flows through the first fuse part 35a and the second fuse part 35b having the small cross-section area in the normal circuit operation, the scattering prevention pattern 40 can shield the electromagnetic noise. Moreover, the scattering prevention pattern 40 can radiate and diffuse the heat of each fuse pattern generated in the normal circuit operation, and it can suppress the temperature rise of the multilayer circuit board. In the present embodiment, since the scattering prevention pattern 40 is provided in the outer layer, the heat dissipation from the scattering prevention pattern 40 to the outside can be increased, and the heat radiation effect by the scattering prevention pattern 40 is increased.

In the present embodiment, the first scattering prevention pattern 40a is provided in the layer on one side rather than the first fuse pattern 31a and the second fuse pattern 31b, and the second scattering prevention pattern 40b is provided in the layer on the other side rather than the first fuse pattern 31a and the second fuse pattern 31b. Therefore, it can prevent the fused material and the conductive material of the first fuse pattern 31a and the second fuse pattern 31b from scattering to the one side and the other side of the breaking mechanism 30. Since the first and the second scattering prevention patterns 40a, 40b are disposed so as to cover whole the first fuse part 35a and the second fuse part 35b, the scattering preventing effect, the shielding effect of the electromagnetic noise, and the heat radiation effect are increased.

The voltage applied to the first terminal pattern 21 and the second terminal pattern 22 of the breaking mechanism 30 (in this example, the voltage Vin of the first external connection terminal 1) is not specified. But, generally, when the applied voltage exceeds 20V, the arc discharge is easily generated, and it becomes easy to obtain the breaking effect of the arc discharge of the present disclosure. That is to say, if the voltage supplied to the breaking mechanism 30 is a DC voltage greater than or equal to 20V, it is easy to obtain the breaking effect of the arc discharge of the present disclosure. Even if the supply voltage is less than 20V and the arc discharge is not generated after fusing, the scattering preventing effect of the fused material is obtained by providing the fuse pattern in the inner layer, and the scattering preventing effect of the fused material, the shielding effect of the electromagnetic noise, and the heat radiation effect are obtained by providing the scattering prevention pattern 40.

### 5. Embodiment 5

Next, the power converter according to Embodiment 5 will be explained. The explanation for constituent parts the same as those in Embodiment 4 will be omitted. The basic configuration of the power converter according to the present embodiment is the same as that of Embodiment 4. The configuration of the first and the second fuse patterns 31a, 31b is different from that of Embodiment 4.

Similar to Embodiment 4, the breaking mechanism 30 is formed by a multilayer circuit board in which a plurality of conductive patterns and a plurality of insulating members are laminated. The breaking mechanism 30 is provided with the first terminal pattern 21 and the second terminal pattern 22 which are connected to the wiring member 25, the first fuse pattern 31a and the second fuse pattern 31b which are connected in parallel between the first terminal pattern 21 and the second terminal pattern 22, and the scattering prevention pattern 40.

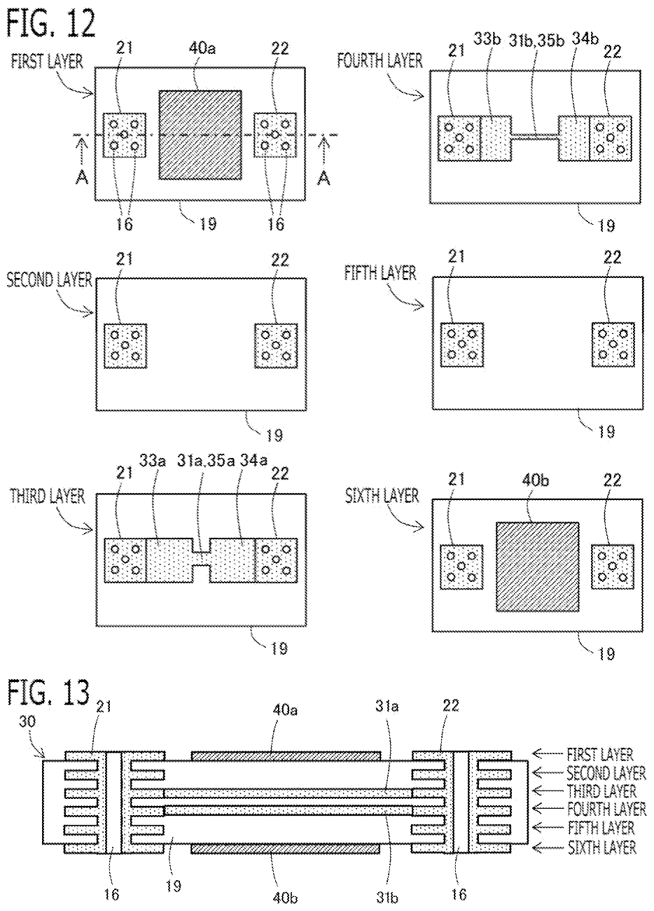

Similar to Embodiment 4, the breaking mechanism 30 is formed by the multilayer circuit board of six layers. FIG. 12 shows a plan view of each layer, and FIG. 13 shows a cross-sectional view which cut the all six layers by a plane perpendicular to the circuit board at the A-A cross section position of FIG. 12.

Since the first terminal pattern 21, the second terminal pattern 22, the first scattering prevention pattern 40a, and the second scattering prevention pattern 40b are constituted similar to Embodiment 4, detailed explanation is omitted.

Similar to Embodiment 4, the first fuse pattern 31 and the second fuse pattern 31 are provided in inner layers. The first fuse pattern 31a and the second fuse pattern 31b are connected in parallel between the first terminal pattern 21 and the second terminal pattern 22.

Unlike Embodiment 4, the first fuse pattern 31 and the second fuse pattern 31 are provided in mutually different inner layers. In this example, the first fuse pattern 31a is provided in the third layer, the second fuse pattern 31b is provided in the fourth layer, and the substrate 19 is disposed between the first fuse pattern 31a and the second fuse pattern 31b.

The first fuse pattern 31a is provided with a first terminal side base part 33a connected to the first terminal pattern 21 of the third layer, a second terminal side base part 34a connected to the second terminal pattern 22 of the third layer, and a first fuse part 35a which connects between the first terminal side base part 33a and the second terminal side base parts 34a. A cross-section area of the first fuse part 35a becomes smaller than a cross-section area of the first terminal side base part 33a and the second terminal side base part 34a. The first fuse part 35a is a fusing part which fuses when excess current flows. The first fuse part 35a is sealed within the circuit board of the third layer.

The second fuse pattern 31b is provided with a first terminal side base part 33b connected to the first terminal pattern 21 of the fourth layer, a second terminal side base part 34b connected to the second terminal pattern 22 of the fourth layer, and a second fuse part 35b which connects between the first terminal side base part 33b and the second terminal side base parts 34b. A cross-section area of the second fuse part 35b becomes smaller than a cross-section area of the first terminal side base part 33b and the second terminal side base part 34b. The second fuse part 35b is a fusing part which fuses when excess current flows. The second fuse part 35b is sealed within the circuit board of the fourth layer.

The first terminal pattern 21 of the third layer and the first terminal pattern 21 of the fourth layer are connected by the through hole 16, and the second terminal pattern 22 of the third layer and the second terminal pattern 22 of the fourth layer are connected by the through hole 16. Accordingly, the first fuse pattern 31a and the second fuse pattern 31b are connected in parallel between the first terminal pattern 21 and the second terminal pattern 22.

A resistance value of the first fuse part 35a is different from a resistance value of the second fuse part 35b. One or both of the length and the cross-section area of each of the first fuse part 35a and the second fuse part 35b are adjusted, and a resistance value [Ω] of each fuse part is adjusted. The resistance value Ra [Ω] of the first fuse part 35a becomes smaller than the resistance value Rb [Ω] of the second fuse part 35b (Ra<Rb). The length of the first fuse part 35a is shorter than the length of the second fuse part 35b, and the cross-section area of the first fuse part 35a becomes larger than the cross-section area of the second fuse part 35b.

The short-circuit current is divided into the first fuse part 35a and the second fuse part 35b. Similar to Embodiment 4, after the first fuse part 35a fuses first by the short-circuit current, the second fuse part 35b fuses, and the arc discharge is generated in the second fuse part 35b.

Since the second fuse part 35b is provided in the inner layer, according to the principle explained in Embodiment 1, the arc discharge current can be decreased gradually after the generation of the arc discharge, and current can be broken.

If the first fuse part 35a and the second fuse part 35b are provided in the same layer, and if the first fuse part 35a and the second fuse part 35b are disposed closely, the fused material of the first fuse part 35a and the substrate 19 destroyed by the energy at fusing may scatter and damage the second fuse part 35b. If the second fuse part 35b is damaged, the fusing performance of the second fuse part 35b changes, the fusing time and the generation of the arc discharge after fusing are influenced, and the excess current may not be broken.

On the other hand, in the present embodiment, the first fuse part 35a and the second fuse part 35b are formed in mutually different layers, and the substrate 19 is disposed therebetween. If the substrate 19 has a certain thickness, since it can be suppressed that the fused material of the first fuse part 35a penetrates the substrate 19 and damages the second fuse part 35b, the fusing performance of the second fuse part 35b does not change, and the desired breaking function of excess current can be achieved.

Since the first fuse part 35a and the second fuse part 35b are formed in mutually different inner layers and the substrate 19 with low thermal conductivity is disposed therebetween, it can be suppressed that the thermal interference occurs by mutual heat generation, and the temperature rise increases when generating heat by energization in the normal circuit operation.

In Embodiment 4, between the first fuse part 35a and the second fuse parts 35b, the interval is provided so that the damage of the second fuse part 35b by fusing of the first fuse part 35a and the thermal interference between the fuse parts can be suppressed.

In the present embodiment, viewing in the normal direction of the circuit board face, the first fuse part 35a and the second fuse part 35b overlap with each other. By the substrate 19 disposed therebetween, the damage of the second fuse part 35b by fusing of the first fuse part 35a and the thermal interference between the fuse parts can be suppressed. By overlapping, the width of the multilayer circuit board can be narrowed and miniaturization can be achieved.

### 6. Embodiment 6

Next, the power converter according to Embodiment 6 will be explained. The explanation for constituent parts the same as those in each of Embodiments 4 and 5 will be omitted. The basic configuration of the power converter according to the present embodiment is the same as that of Embodiment 4 or 5. The configuration of the first and the second scattering prevention patterns 40a, 40b is different from that of Embodiment 4 or 5.

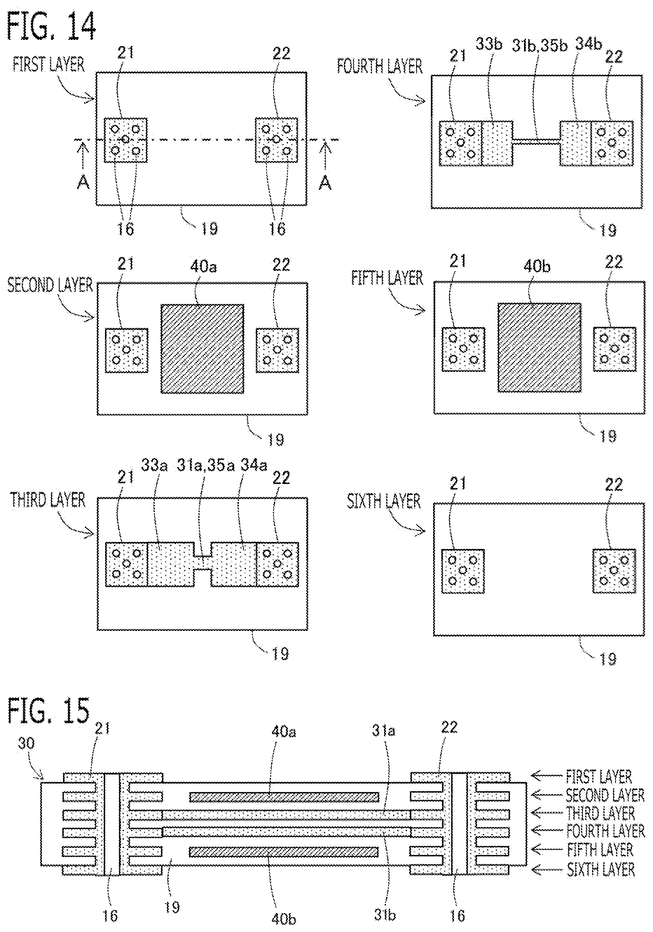

Similar to Embodiment 4, the breaking mechanism 30 is formed by the multilayer circuit board of six layers. FIG. 14 shows a plan view of each layer, and FIG. 15 shows a cross-sectional view which cut the all six layers by a plane perpendicular to the circuit board at the A-A cross section position of FIG. 14.

Since the first terminal pattern 21 and the second terminal pattern 22 are configured similar to Embodiment 1, detailed explanation is omitted. Since the first fuse pattern 31a and the second fuse pattern 31b are configured similar to Embodiment 5, detailed explanation is omitted. The first fuse pattern 31a and the second fuse pattern 31b may be configured similar to Embodiment 4.

Even in the present embodiment, the scattering prevention pattern 40 is provided in a layer different from the first fuse pattern 31a and the second fuse pattern 31b. Viewing in the normal direction of the circuit board face, the scattering prevention pattern 40 overlaps with at least a part of the fusing part (in this example, the first fuse part 35a) of the first fuse pattern 31a, and at least a part of the fusing part (in this example, the second fuse part 35b) of the second fuse pattern 31b.

Even in the present embodiment, a plurality of scattering prevention patterns 40 are provided in mutually different layers. The first scattering prevention pattern 40a is provided in the layer on one side rather than the first fuse pattern 31a and the second fuse pattern 31b, and the second scattering prevention pattern 40b is provided in the layer on the other side rather than the first fuse pattern 31a and the second fuse pattern 31b.

Unlike Embodiments 4 and 5, the first scattering prevention pattern 40a and the second scattering prevention pattern 40b are provided in the inner layer. The first scattering prevention pattern 40a is provided in the second layer of the inner layer, and the second scattering prevention pattern 40b is provided in the fifth layer of the inner layer.

By providing the scattering prevention pattern 40 in the inner layer, the scattering prevention pattern 40 can be disposed close to the first fuse part 35a and the second fuse part 35b, and the scattering preventing effect, the shielding effect of the electromagnetic noise, and the heat radiation effect by the scattering prevention pattern 40 can be increased.

By providing the scattering prevention pattern 40 in the inner layer, since the both sides of the scattering prevention pattern 40 are reinforced by the substrate 19, the strength of the scattering prevention pattern 40 can be increased rather than the case of providing in the outer layer. Accordingly, the scattering preventing effect by the scattering prevention pattern 40 can be increased.

### 7. Embodiment 7

Next, the power converter according to Embodiment 7 will be explained. The explanation for constituent parts the same as those in each of Embodiments 4 to 6 will be omitted. The basic configuration of the power converter according to the present embodiment is the same as that of any one of Embodiments 4 to 6. The configuration of the scattering prevention pattern 40, the first fuse pattern 31a, and the second fuse pattern 31b is different from that of Embodiments 4 to 6.

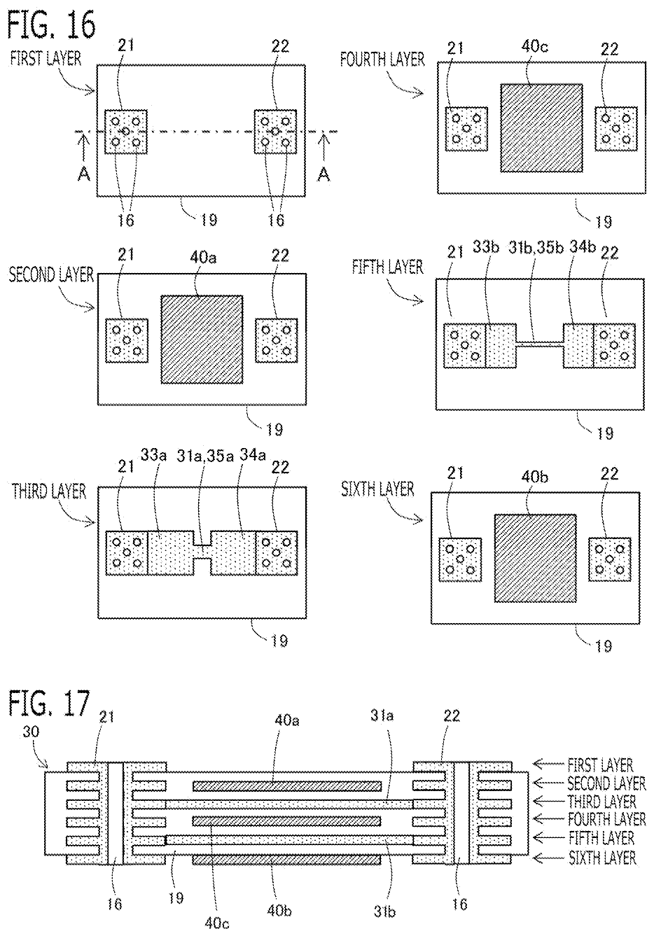

Similar to Embodiment 4, the breaking mechanism 30 is formed by the multilayer circuit board of six layers. FIG. 16 shows a plan view of each layer, and FIG. 17 shows a cross-sectional view which cut the all six layers by a plane perpendicular to the circuit board at the A-A cross section position of FIG. 16.

Since the first terminal pattern 21 and the second terminal pattern 22 are configured similar to Embodiments 4 to 6, detailed explanation is omitted. Similar to Embodiment 5, the first fuse pattern 31 and the second fuse pattern 31 are provided in mutually different inner layers. Since the shapes of the first fuse pattern 31a and the second fuse pattern 31b themselves is similar to Embodiments 5 and 6, explanation is omitted.

In the present embodiment, the first fuse pattern 31 and the second fuse pattern 31 are provided in different inner layers, while interposing one or more layers therebetween. The first fuse pattern 31a is provided in the third layer, the second fuse pattern 31b is provided in the fifth layer, and the fourth layer is interposed between the first fuse pattern 31a of the third layer, and the second fuse pattern 31b of the fifth layer.

Then, a third scattering prevention pattern 40c is provided in a layer between the first fuse pattern 31a and the second fuse pattern 31b (in this example, the fourth layer).

According to this configuration, the third scattering prevention pattern 40c can suppress that the fused material of the first fuse pattern 31a and the substrate 19 destroyed by the energy at fusing scatters to the second fuse pattern 31b side, the damage to the second fuse pattern 31b can be further suppressed.

By providing the third scattering prevention pattern 40c between the first fuse pattern 31a and the second fuse pattern 31b, the scattering prevention pattern 40 can be disposed close to the first fuse part 35a and the second fuse part 35b, and the scattering preventing effect, the shielding effect of the electromagnetic noise, and the heat radiation effect by the scattering prevention pattern 40 can be increased.

The third scattering prevention pattern 40c can suppress that the electromagnetic noise at breaking of one fuse part and in the normal operation is transmitted to the other fuse part, and malfunction of the electrical components is caused.

Since the scattering preventing effect is increased by the third scattering prevention pattern 40c, the substrate 19 between the first fuse pattern 31a and the third scattering prevention pattern 40c, and the substrate 19 between the second fuse pattern 31b and the third scattering prevention pattern 40c can be made thin. And, the effect of radiating and diffusing heat of each fuse part to the third scattering prevention pattern 40c can be increased, and the temperature rise of the circuit board can be suppressed.

The first scattering prevention pattern 40a is provided in the layer on one side rather than the first fuse pattern 31a and the second fuse pattern 31b, and the second scattering prevention pattern 40b is provided in the layer on the other side rather than the first fuse pattern 31a and the second fuse pattern 31b.

The first scattering prevention pattern 40a is provided in the second layer of the inner layer, and the second scattering prevention pattern 40b is provided in the sixth layer of the outer layer. The number of layers and arrangement may be changed so that the first scattering prevention pattern 40a is provided in the outer layer, and the second scattering prevention pattern 40b is provided in the inner layer. Alternatively, the number of layers and arrangement may be changed so that both of the first and the second scattering prevention patterns 40a, 40b are provided in the inner layers or the outer layers.

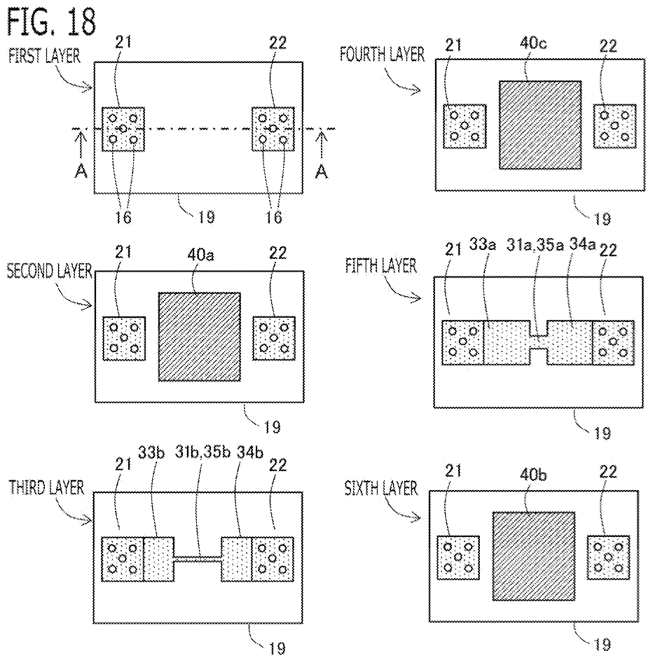

As shown in FIG. 18, the first fuse pattern 31a and the second fuse pattern 31b of FIG. 16 may be replaced. That is to say, the second fuse pattern 31b may be provided in the third layer, and the first fuse pattern 31a may be provided in the fifth layer.

In this way, the layer (the third layer) in which the second fuse part 35b with the larger resistance value is provided may be disposed closer to the central layer (in this example, the third layer and the fourth layer) rather than the layer (the fifth layer) in which the first fuse part 35a with the smaller resistance value is provided.

According to this configuration, since the second fuse part 35b in which the arc discharge is generated is disposed close to the central layer, the second fuse part 35b can be surrounded more firmly by the substrate 19, the arrangement space of the second fuse part 35b in the substrate 19 is maintained at generation of the arc discharge, it can be suppressed that the cross-section area of the arc discharge and the sealing property change, and it becomes easy to maintain the current limitation performance.

### 8. Embodiment 8

Next, the power converter according to Embodiment 8 will be explained. The explanation for constituent parts the same as those in each of Embodiments 4 to 7 will be omitted. The basic configuration of the power converter according to the present embodiment is the same as that of any one of Embodiments 4 to 7. But, the configuration of the scattering prevention pattern 40 is different from that of Embodiments 4 to 7.

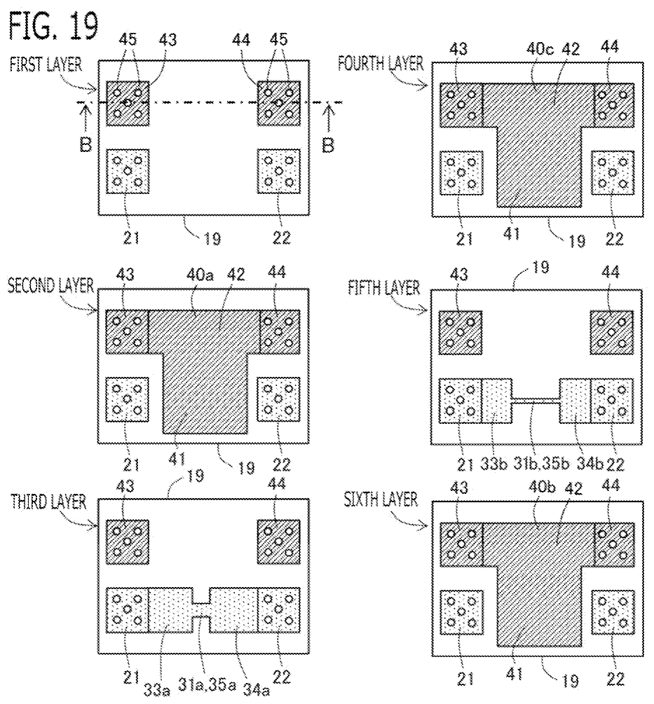

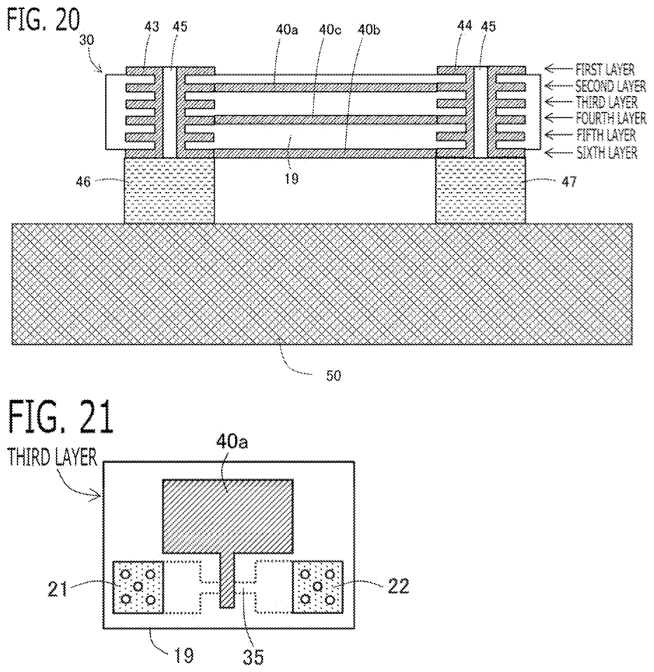

Similar to Embodiment 1, the breaking mechanism 30 is formed by the multilayer circuit board of six layers. FIG. 19 shows a plan view of each layer, and FIG. 20 shows a cross-sectional view which cut the all six layers by a plane perpendicular to the circuit board at the B-B cross section position of FIG. 19.

In the present embodiment, the width of the multilayer circuit board becomes longer than other embodiments. The width is a distance of the circuit board in the direction orthogonal to the extending direction of the fuse part. Since the first terminal pattern 21 and the second terminal pattern 22 are configured similar to Embodiments 4 to 7, detailed explanation is omitted. Since the first fuse pattern 31a and the second fuse pattern 31b are configured similar to Embodiment 7, in a part of the circuit board on one side in the width direction, detailed explanation is omitted. The first fuse pattern 31a and the second fuse pattern 31b may be configured similar to any one of Embodiments 4 to 6.

Similar to Embodiment 7, the first scattering prevention pattern 40a is provided in the layer on one side rather than the first fuse pattern 31a and the second fuse pattern 31b (in this example, second layer), and the second scattering prevention pattern 40b is provided in the layer on the other side rather than the first fuse pattern 31a and the second fuse pattern 31b (in this example, the sixth layer). Then, the third scattering prevention pattern 40c is provided in the layer between the first fuse pattern 31a and the second fuse pattern 31b (in this example, the fourth layer).

In the present embodiment, the scattering prevention pattern 40 is thermally connected to a heat dissipation member 50. Each scattering prevention pattern 40 is provided with a main part 41 which overlaps with the first fuse part 35a and the second fuse part 35b, viewing in the normal direction of the circuit board face, and a connection part 42 which connects the main part 41 with the heat dissipation member 50 side. The connection part 42 extends from the main part 41 to the other side in the width direction. The connection part 42 is formed of the copper foil similar to the main part 41.

In each layer, the first connection pattern 43 is provided on the other side in the width direction of the first terminal pattern 21 with an interval. The second connection pattern 44 is provided on the other side in the width direction of the second terminal pattern 22 with an interval. The first connection patterns 43 of respective layers are disposed at a position overlapping with each other, viewing in the normal direction of the circuit board face. The first connection patterns 43 of respective layers are connected with each other so as to become the same electric potential by a conductive cylindrical tubular through hole 45 (in this example, five through holes) which penetrates each substrate 19. The second connection patterns 44 of respective layers are disposed at a position overlapping with each other, viewing in the normal direction of the circuit board face. The second connection patterns 44 of respective layers are connected with each other so as to become the same electric potential by a conductive cylindrical tubular through hole 45 (in this example, five through holes) which penetrates each substrate 19. The first and the second connection patterns 43, 44 are formed of a copper foil, and are formed in a rectangular plate shape in this example.

The connection part 42 of each scattering prevention pattern 40 is thermally and electrically connected to the first and the second connection patterns 43, 44 of each layer. The first connection pattern 43 in the outer layer (in this example, the sixth layer) is thermally and electrically connected to the heat dissipation member 50 via a first connection member 46. The second connection pattern 44 in the outer layer (in this example, the sixth layer) is thermally and electrically connected to the heat dissipation member 50 via a second connection member 47. Accordingly, each scattering prevention pattern 40 is thermally and electrically connected to the heat dissipation member 50 via the first and the second connection patterns 43, 44, and the first and the second connection members 46, 47. The scattering prevention pattern 40 of each layer can be thermally and electrically firmly connected to the heat dissipation member 50 by the first and the second connection patterns 43, 44 of each layer and the through holes 45.

The heat dissipation member 50 is a heatsink, a cooler in which a refrigerant circulates, or the like. The heat dissipation member 50 is disposed with an interval from the breaking mechanism 30.

According to this configuration, the temperature of the scattering prevention pattern 40 becomes low by the heat dissipation member 50. And, the effect of radiating and diffusing heat of each fuse part to the scattering prevention pattern 40 can be increased, and the temperature rise of the circuit board can be suppressed.

In the present embodiment, the scattering prevention pattern 40 has a ground potential. The heat dissipation member 50 is connected to the ground. Each scattering prevention pattern 40 is connected to the ground via the first and the second connection patterns 43, 44, the first and the second connection members 46, 47, and the heat dissipation member 50. According to this configuration, the shielding effect of the electromagnetic noise by the scattering prevention pattern 40 can be increased. The scattering prevention pattern 40 and the fuse pattern are different potentials. The heat dissipation member 50 may be floating potential, and the scattering prevention pattern 40 may be floating potential. The scattering prevention pattern 40 may be only thermally connected with the heat dissipation member 50, and may not be electrically connected with the heat dissipation member 50.

Since the configuration of the heat dissipation member 50 is similar to that of Embodiment 3, explanation is omitted.

The layer arrangement of the first fuse pattern 31a, the second fuse pattern 31b, and the scattering prevention pattern 40 may be made similar to any one of Embodiments 4 to 7.

### Example of Conversion

In Embodiments 1 to 3, viewing in the normal direction of the circuit board face, the scattering prevention pattern 40 overlaps with the whole fuse part 35. However, as FIG. 21 shows an example of conversion of Embodiment 1, viewing in the normal direction of the circuit board face, the scattering prevention pattern 40 may overlap with a part of the fuse part 35. Accordingly, as long as a certain scattering preventing effect is obtained, the overlap degree may be an arbitrary degree.

In Embodiments 4 to 8, viewing in the normal direction of the circuit board face, the scattering prevention pattern 40 overlaps with whole of the first fuse part 35a and the second fuse part 35b. However, as FIG. 22 shows an example of conversion of Embodiment 4, viewing in the normal direction of the circuit board face, the scattering prevention pattern 40 may overlap with a part of the first fuse part 35a and a part of the second fuse part 35b. Accordingly, as long as a certain scattering preventing effect is obtained, the overlap degree may be an arbitrary degree.

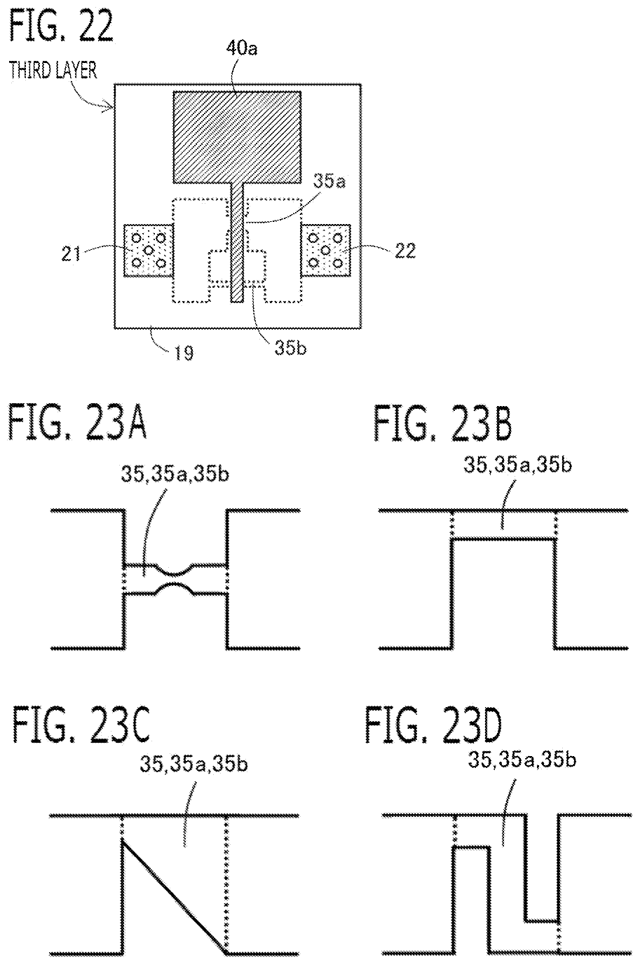

In each embodiment, each fuse part 35, 35a, 35b is formed in the rectangular plate shape. As long as the cross-section area of each fuse part 35, 35a, 35b is smaller than the cross-section area of other parts, each fuse part 35, 35a, 35b fuses when the short-circuit current flows, and each fuse part 35, 35a, 35b can break the arc discharge, each fuse part 35, 35a, 35b may be any shape. For example, as shown in FIG. 23A to FIG. 23D, a notch may be provided on one side or the both sides of the plate-like pattern to reduce a cross-section area. The shape of a notch may be any shape, such as a triangle, a pentagon, a trapezoid, a lozenge, a parallelogram, a circular, or an oval, other than the rectangle. A plurality of notches may be provided. A plurality of notches may be disposed alternately in zigzag or irregularly at different positions in the longitudinal directions of wiring.

In each embodiment, the breaking mechanism 30 is the fuse for breaking the excess current of the DC-DC converter. However, the breaking mechanism 30 may be provided in various kinds of circuits, as an arrester which breaks surge current other than steady excess current.

In each embodiment, the first and the second terminal patterns 21, 22, the through hole 16, and the fuse pattern 31 are made of copper. However, each of these conductive members may be formed of other conductive materials other than copper, such as silver (Ag), gold (Au), tin (Sn), aluminum (Al), nickel (Ni), or these alloys. Each of these conductive members may be formed of a single material, or may be formed of a plurality of different materials. The inner side of the through hole 16 may not be space, and may be filled with the conductive material. If the first and the second terminal patterns 21, 22 which are disposed in each layer are electrically connected, the inner side of the through hole 16 is space. But the inner side of the through hole 16 may be filled with the insulating material.

In each embodiment, the breaking mechanism 30 is connected to the high potential side terminal 1H side of the first external connection terminal 1. However, the breaking mechanism 30 may be connected in series on the wiring member 25 which connects between the low potential side terminal 1L of the first external connection terminal 1, and the low voltage side of the semiconductor circuit 5. The breaking mechanism 30 may be connected to the high potential side terminal 2H side, or the low potential side terminal 2L side of the second external connection terminal 2. The breaking mechanism 30 may be connected in series to any parts on the circuit which can break excess current. A plurality of breaking mechanisms 30 may be provided.

In each embodiment, the power converter is the insulated type DC-DC converter. However, the power converter may be various kinds of power converters, such as a non-insulated DC-DC converter, an inverter, and a rectifier. The power converter may not be a step-down type converter which steps down voltage from the first external connection terminal 1 to the second external connection terminal 2. The power converter may be a step-up type converter which steps up voltage from the first external connection terminal 1 to the second external connection terminal 2. Alternatively, the voltage of the second external connection terminal 2 may be the same as the voltage of the first external connection terminal 1.

In each embodiment, the switching device is provided as the semiconductor element. However, the diode may be provided as the semiconductor element.

In each embodiment, the breaking mechanism 30 is provided in the power converter. However, the breaking mechanism 30 may be provided in various kinds of circuits other than the power converter. The breaking mechanism 30 may be distributed as a circuit component.

In each embodiment, the breaking mechanism 30 is formed by the multilayer circuit board. However, not only the breaking mechanism 30 but also other parts (for example, wiring member) of the power converter may be formed by the multilayer circuit board.

In Embodiments 1 to 3, the breaking mechanism 30 is formed by the multilayer circuit board of six layers. However, in Embodiment 1, the multilayer circuit board may be a multilayer circuit board of three or more layers which has at least one inner layer. For example, the multilayer circuit board may be a multilayer circuit board of three layers, the first scattering prevention pattern 40a may be provided in the first layer of the outer layer, the fuse pattern 31 may be provided in the second layer of the inner layer, and the second scattering prevention pattern 40b may be provided in the third layer of the outer layer. In Embodiment 2, the multilayer circuit board may be a multilayer circuit board of four or more layers which has at least three inner layers.

In Embodiments 4 to 8, the breaking mechanism 30 is formed by the multilayer circuit board of six layers. However, in Embodiment 4, the multilayer circuit board may be a multilayer circuit board of three or more layers which has at least one inner layer. For example, the multilayer circuit board may be a multilayer circuit board of three layers, the first scattering prevention pattern 40a may be provided in the first layer of the outer layer, the first fuse pattern 31a and the second fuse pattern 31b may be provided in the second layer of the inner layer, and the second scattering prevention pattern 40b may be provided in the third layer of the outer layer. In Embodiment 5, the multilayer circuit board may be a multilayer circuit board of four or more layers which has at least two inner layers. For example, the multilayer circuit board may be a multilayer circuit board of four layers, the first scattering prevention pattern 40a may be provided in the first layer of the outer layer, the first fuse pattern 31a may be provided in the second layer of the inner layer, the second fuse pattern 31b may be provided in the third layer of the inner layer, and the second scattering prevention pattern 40b may be provided in the fourth layer of the outer layer. In Embodiment 6, the multilayer circuit board may be a multilayer circuit board of six or more layers which has at least four inner layers. In Embodiment 7, the multilayer circuit board may be a multilayer circuit board of five or more layers which has at least three inner layers.

Although the present disclosure is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments. It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

What is claimed is:

1. A power converter comprising:
a semiconductor element;
a breaking mechanism that breaks current when excessive current flows; and
a wiring member that connects the semiconductor element and the breaking mechanism,
wherein the breaking mechanism is formed by a multilayer circuit board in which a plurality of conductive patterns and a plurality of insulating members are laminated, and is provided with one or two fuse patterns which fuse when excessive current flows, and a scattering prevention pattern,
wherein the one or two fuse patterns are provided in an inner layer, and
wherein the scattering prevention pattern is provided in a layer different from the one or two fuse patterns, and overlaps with at least a part of a fusing part of each of the one or two fuse patterns, viewing in a normal direction of a circuit board face.

2. The power converter according to claim 1,
wherein the breaking mechanism is formed by a printed circuit board.

3. The power converter according to claim 1,
wherein a plurality of the scattering prevention patterns are provided in mutually different layers.

4. The power converter according to claim 3,
wherein the plurality of scattering prevention patterns are provided in at least a layer on one side and a layer on the other side in the normal direction of the circuit board face rather than the one or two fuse patterns.

5. The power converter according to claim 1,
wherein the scattering prevention pattern is provided in an inner layer.

6. The power converter according to claim 1,
wherein the scattering prevention pattern has a ground potential.

7. The power converter according to claim 1,
wherein the scattering prevention pattern is thermally connected to a heat dissipation member.

8. The power converter according to claim 1,
wherein a voltage supplied to the breaking mechanism is a DC voltage greater than or equal to 20V.

9. The power converter according to claim 1,
wherein as the two fuse patterns, a first fuse pattern and a second fuse pattern which are connected in parallel between a first terminal pattern and a second terminal pattern which are connected to the wiring member are provided,
wherein a resistance value of the first fuse pattern is different from a resistance value of the second fuse pattern, and
wherein the scattering prevention pattern overlaps with at least a part of a fusing part of the first fuse pattern, and at least a part of a fusing part of the second fuse pattern, viewing in the normal direction of the circuit board face.

10. The power converter according to claim 9,
wherein the first fuse pattern and the second fuse pattern are provided in mutually different inner layers.

11. The power converter according to claim 10,
wherein a resistance value of the second fuse pattern is larger than a resistance value of the first fuse pattern, and
wherein the layer provided with the second fuse pattern is closer to a central layer than the layer provided with the first fuse pattern.

12. The power converter according to claim 9,
wherein one or more layers are interposed between the first fuse pattern and the second fuse pattern, and the first fuse pattern and the second fuse pattern are provided in mutually different inner layers, and
wherein at least the three scattering prevention patterns are provided in a layer between the first fuse pattern and the second fuse pattern, and a layer on one side and a layer on the other side in the normal direction of the circuit board face rather than the first fuse pattern and the second fuse pattern, respectively.

13. A breaking mechanism that breaks current when excessive current flows and is formed by a multilayer circuit board in which a plurality of conductive patterns and a plurality of insulating members are laminated, the breaking mechanism comprising:
one or two fuse patterns which fuse when excessive current flows, and
a scattering prevention pattern,
wherein the one or two fuse patterns are provided in an inner layer, and
wherein the scattering prevention pattern is provided in a layer different from the one or two fuse patterns, and overlaps with at least a part of a fusing part of each of the one or two fuse patterns, viewing in a normal direction of a circuit board face.
